(19) United States
(12) Patent Application Publication
(10) Pub. No.: US 2024/0389407 A1
(43) Pub. Date: Nov. 21, 2024

(54) DISPLAY SUBSTRATES, DISPLAY PANELS AND DISPLAY APPARATUSES

(71) Applicants: Chengdu BOE Optoelectronics Technology Co., Ltd., Chengdu, Sichuan (CN); BOE Technology Group Co., Ltd., Beijing (CN)

(72) Inventors: Xingyu CHEN, Beijing (CN); Lian XIANG, Beijing (CN); Hongting LU, Beijing (CN); Yanping REN, Beijing (CN); Yan YANG, Beijing (CN); Chao YANG, Beijing (CN)

(21) Appl. No.: 18/034,048

(22) PCT Filed: Feb. 23, 2022
(86) PCT No.: PCT/CN2022/077463

§ 371 Date: Apr. 26, 2023

(51) Int. Cl. H10K 59/131

(52) U.S. Cl. CPC H10K 59/131

(57) ABSTRACT

A display substrate, a display panel and a display apparatus are provided. The display substrate includes a display region and at least partial region of the display region is a transparent display region. The display substrate includes a plurality of pixels located in the transparent display region. The pixels each include a plurality of sub-pixels and the sub-pixels each include an organic light-emitting element (220) and a pixel circuit (221). The organic light-emitting element (220) includes a first electrode, a second electrode and an organic light-emitting material between the first electrode and the second electrode. The first electrodes of the sub-pixels are electrically connected with the pixel circuits (221); and a number of the first electrodes is greater than a number of the second electrodes. The display substrate is further provided with first power supply signal lines (VDD1) connected with the pixel circuits and second power supply signal lines (VSS) connected with the second electrodes. The first power supply signal lines (VDD1) include first sub-power supply signal lines (VDD11) extending along a first direction and second sub-power supply signal lines (VDD12) extending along a second direction; and/or, the second power supply signal lines (VSS) include third sub-power supply signal lines (VSS1) extending along the first direction and fourth sub-power supply signal lines (VSS2) extending along the second direction.

### TECHNICAL FIELD

The present application relates to the field of display technologies, and in particular to a display substrate, a display panel and a display apparatus.

### BACKGROUND

The Organic Light-Emitting Diode (OLED) displays are widely applied in the fields such as display, illumination and intelligent wearing due to its self-luminosity, low drive voltage, high light emitting efficiency, short response time, high definition and contrast, wide temperature range, availability of flexible display and the like.

### SUMMARY

The embodiments of the present application provide a display substrate, a display panel and a display apparatus.

According to a first aspect of embodiments of the present application, there is provided a display substrate. The display substrate includes a display region. At least a partial region of the display region is a transparent display region; the display substrate includes a base substrate and a plurality of pixels located on the base substrate and in the transparent display region. The pixels each include a plurality of sub-pixels and the sub-pixels each include an organic light-emitting element and a pixel circuit for driving the organic light-emitting element. The organic light-emitting element includes a first electrode, a second electrode and an organic light-emitting material between the first electrode and the second electrode. The first electrodes of the sub-pixels are electrically connected with the pixel circuits. A number of the first electrodes is greater than a number of the second electrodes.

The display substrate is further provided with first power supply signal lines and second power supply signal lines. The pixel circuits are connected with the first power supply signal lines, and the second electrodes are connected with the second power supply signal lines. The first power supply signal lines include first sub-power supply signal lines extending along a first direction and second sub-power supply signal lines extending along a second direction; and/or, the second power supply signal lines include third sub-power supply signal lines extending along the first direction and fourth sub-power supply signal lines extending along the second direction. The first direction intersects with the second direction.

In an embodiment, the display substrate further includes overlapping portions in electrical connection with the second power supply signal lines, and the second electrodes of at least two adjacent pixels are in contact with a same overlapping portion.

In an embodiment, when the second power supply signal lines include the third sub-power supply signal lines extending along the first direction and the fourth sub-power supply signal lines extending along the second direction, the second electrodes of at least two adjacent pixels are electrically connected with a third sub-power supply signal lines through a same overlapping portion, or electrically connected with a fourth sub-power supply signal lines through a same overlapping portion.

In an embodiment, a multitude of the overlapping portions arranged in the first direction are electrically connected through a third sub-power supply signal line, and/or, a multitude of the overlapping portions arranged in the second direction are electrically connected through a fourth sub-power supply signal line.

In an embodiment, the display substrate further includes overlapping portions in electrical connection with the second power supply signal lines, the second electrodes of at least four adjacent pixels are in contact with a same overlapping portion, and the four adjacent pixels are arranged into two rows and two columns.

In an embodiment, when the second power supply signal lines include the third sub-power supply signal lines extending along the first direction and the fourth sub-power supply signal lines extending along the second direction, the second electrodes of at least four adjacent pixels are electrically connected to a third sub-power supply signal line and a fourth sub-power supply signal line through a same overlapping portion.

In an embodiment, the display substrate includes a plurality of overlapping portions, and at least one overlapping portion is electrically connected with other overlapping portions arranged in the first direction through a third sub-power supply signal line, and electrically connected with other overlapping portions arranged in the second direction through a fourth sub-power supply signal line.

In an embodiment, the display substrate further includes electrode connection structures connected with the second electrodes, each of the second electrodes in contact with a same overlapping portion is connected to a same electrode connection structure, and the second electrodes are in contact with the overlapping portion through the electrode connection structure.

In an embodiment, when the first power supply signal lines include the first sub-power supply signal lines extending along the first direction and the second sub-power supply signal lines extending along the second direction, the pixel circuits of at least two adjacent pixels are connected to a same first sub-power supply signal line or a same second sub-power supply signal line of the first power supply signal lines.

In an embodiment, when the first power supply signal lines include the first sub-power supply signal lines extending along the first direction and the second sub-power supply signal lines extending along the second direction, at least one first sub-power supply signal line is electrically connected to the pixel circuits through the second sub-power supply signal lines;

at least part of the second sub-power supply signal lines and the first sub-power supply signal lines are disposed in different layers.

In an embodiment, the display substrate further includes drive signal lines disposed in the same layer as the first sub-power supply signal lines, where the drive signal lines are configured to provide drive signals for the pixel circuits; an orthographic projection of the part of the second sub-power supply signal lines disposed in a different layer from the first sub-power supply signal lines on the base substrate is overlapped with an orthographic projection of the drive signal lines on the base substrate.

In an embodiment, an orthographic projection of the first power supply signal lines on the base substrate is not overlapped with an orthographic projection of the second power supply signal lines on the base substrate.

In an embodiment, when the first power supply signal lines include the first sub-power supply signal lines extending along the first direction and the second sub-power supply signal lines extending along the second direction and the second power supply signal lines include the third sub-power supply signal lines extending along the first direction and the fourth sub-power supply signal lines extending along the second direction, the first power supply signal lines further include a plurality of first connection segments extending along the second direction; the second power supply signal lines further include a plurality of second connection segments extending along the second direction; each of the first sub-power supply signal lines includes a plurality of first sub-signal segments arranged in a spacing along the first direction, each of the second sub-power supply signal lines includes a plurality of second sub-signal segments arranged in a spacing along the second direction, and each of the first sub-signal segments is connected with at least one second sub-signal segment; each of the third sub-power supply signal lines includes a plurality of third sub-signal segments arranged in a spacing along the first direction, each of the fourth sub-power supply signal lines includes a plurality of fourth sub-signal segments arranged in a spacing along the second direction, and each of the third sub-signal segments is connected with at least one fourth sub-signal segment;

adjacent first sub-signal segments along the second direction are connected through a first connection segment, and adjacent third sub-signal segments along the second direction are connected through a second connection segment; an orthographic projection of at least one first connection segment on the base substrate is located between orthographic projections of two adjacent third sub-signal segments on the base substrate; an orthographic projection of at least one second connection segment on the base substrate is located between orthographic projections of two adjacent first sub-signal segments on the base substrate.

In an embodiment, the transparent display region includes light-emitting regions and non-light-emitting regions; the pixels are disposed in the light-emitting regions;

the display substrate is further provided with a plurality of drive signal lines; a width of a part of at least one drive signal line located in the light-emitting regions is greater than a width of a part located in the non-light-emitting regions.

In an embodiment, the drive signal lines include scan signal lines which are configured to provide scan signals for the pixels;

a width of a part of at least one scan signal line located in the light-emitting regions is greater than a width of a part located in the non-light-emitting regions; the part of the scan signal line located in the light-emitting regions has a width of 3.5 μm to 5.5 μm, and the part of the scan signal line located in the non-light-emitting regions has a width of 2 μm to 3.5 μm.

In an embodiment, the pixel circuits include drive transistors, and the display substrate further includes an active semiconductor layer including a channel of a drive transistor of each sub-pixel;

in at least one pixel, the channel of the drive transistor of at least one sub-pixel includes a first section, a second section, a third section, a fourth section and a fifth section connected in sequence, the first section, the third section and the fifth section all extend along the second direction, and the second section and the fourth section both extend along the first direction; the channel of the drive transistor of at least one sub-pixel includes a sixth section, a seventh section, and an eighth section connected in sequence, the sixth section and the eighth section both extend along the second direction, and the seventh section extends along the first direction.

In an embodiment, the display substrate further includes a shielding line and a reset power supply signal line, the reset power supply signal line is configured to provide reset power supply signals for the sub-pixels; and the shielding line is electrically connected with the reset power supply signal line.

In an embodiment, the transparent display region includes light-emitting regions and non-light-emitting regions, and the pixels are disposed in the light-emitting regions; the display substrate further includes a pixel definition layer provided with openings located in the non-light-emitting regions;

at least a part of an orthographic projection of the openings on the base substrate is located outside an orthographic projection of the second electrodes on the base substrate, an orthographic projection of the second power supply signal lines on the base substrate and an orthographic projection of the first power supply signal lines on the base substrate.

In an embodiment, the display substrate further includes a frame region located at at least one side of the display region. The display substrate further includes an auxiliary trace located in the frame region, and the auxiliary trace is electrically connected with the second electrodes; the auxiliary trace includes a first conductive film layer and a second conductive film layer located at a side of the first conductive film layer away from the base substrate. An edge, close to the display region, of an orthographic projection of the first conductive film layer on the base substrate is located within an edge, close to the display region, of an orthographic projection of the second conductive film layer on the base substrate.

According to a second aspect of embodiments of the present application, there is provided a display panel, including the above display substrate.

According to a third aspect of embodiments of the present application, there is provided a display apparatus including the above display panel.

In the display substrate, the display panel and the display apparatus provided by the embodiments of the present application, since the number of the first electrodes is greater than the number of the second electrodes, at least two sub-pixels share one second electrode; compared with the solution in which the second electrode of each sub-pixel is disposed independently, at least two sub-pixels in the embodiments of the present application share one second electrode, so as to reduce a total area of the second electrodes of the transparent display region, thus helping increase the light transmission rate of the transparent display region of the display substrate; disposing one of the first power supply signal lines and the second power supply signal lines as a grid-shaped structure helps to reduce a voltage drop of the first power supply signal lines and the second power supply signal lines and increase the uniformity of the display effect of the display substrate.

### BRIEF DESCRIPTION OF THE DRAWINGS

FIG. 1 is a circuit schematic diagram illustrating a pixel circuit according to an exemplary embodiment of the present application.

FIGS. 2 to 7 are partial schematic diagrams illustrating various layers of a display substrate according to an exemplary embodiment of the present application, where FIG. 3 is an enlarged view of part of FIG. 2.

FIG. 8 is a schematic diagram of overlaying of multiple film layers of a display substrate according to an exemplary embodiment of the present application.

FIG. 9 is a schematic diagram illustrating a part of second conductive layer of a display substrate according to an exemplary embodiment of the present application.

FIG. 10 is a schematic diagram illustrating a part of third conductive layer of a display substrate according to an exemplary embodiment of the present application.

FIG. 11 is a partial schematic diagram of overlaying of a third conductive layer and a second conductive layer of a display substrate according to an exemplary embodiment of the present application.

FIG. 12 is a partial schematic diagram of overlaying of multiple film layers of a display substrate according to an exemplary embodiment of the present application.

FIG. 13 is a schematic diagram illustrating a part of second conductive layer of a display substrate according to another exemplary embodiment of the present application.

FIG. 14 is a schematic diagram illustrating a part of third conductive layer of a display substrate according to another exemplary embodiment of the present application.

FIG. 15 is a partial schematic diagram of overlaying of a third conductive layer and a second conductive layer of a display substrate according to another exemplary embodiment of the present application.

FIG. 16 is a partial schematic diagram of overlaying of multiple film layers of a display substrate according to another exemplary embodiment of the present application.

FIG. 17 is a partial schematic diagram of overlaying of a first power supply signal line and a second power supply signal line of a display substrate according to an exemplary embodiment of the present application.

FIG. 18 is a partial schematic diagram of overlaying of multiple film layers of a display substrate according to an exemplary embodiment of the present application.

### DETAILED DESCRIPTION OF THE EMBODIMENTS

Exemplary embodiments will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present application. Rather, they are merely examples of apparatuses and methods consistent with some aspects of the present application as detailed in the appended claims.

The terms used in the present application are for the purpose of describing particular examples only, and are not intended to limit the present application. Terms determined by “a”, “the” and “said” in their singular forms in the present application and the appended claims are also intended to include plurality, unless clearly indicated otherwise in the context. It should also be understood that the term “and/or” as used herein refers to and includes any and all possible combinations of one or more of the associated listed items.

It is to be understood that, although the terms “first,” “second,” “third,” and the like may be used in the present application to describe various information, such information should not be limited to these terms. These terms are only used to distinguish one category of information from another. For example, without departing from the scope of the present application, first information may be referred as second information; and similarly, the second information may also be referred as the first information. Depending on the context, the term “if” as used herein may be interpreted as “when” or “upon” or “in response to determining”.

The embodiments of the present application provide a display substrate, a display panel and a display apparatus. The display substrate, the display panel and the display apparatus in the embodiments of the present application will be detailed below in combination with accompanying drawings. In a case of no conflict, the features of the following embodiments can be mutually supplemented or combined.

The embodiments of the present application provide a display substrate, a display panel and a display apparatus. The display substrate, the display panel and the display apparatus in the embodiments of the present application will be detailed below in combination with accompanying drawings. In a case of no conflict, the features of the following embodiments can be mutually supplemented or combined.

An embodiment of the present application provides a display substrate. The display substrate includes a display region and at least partial region of the display region is a transparent display region.

In an embodiment, the entirety of the display region is a transparent display region, that is, the display substrate is a transparent display substrate. The transparent display region indicates that the display region includes a sub-display region and a light transmitting region. The sub-display region refers to a region with pixels and the light transmitting region refers to a region without pixels; or, the sub-display region refers to a region with a pixel circuit and the light transmitting region refers to a region without a pixel circuit. In another embodiment, a part of the display region is a transparent display region, and other part is a non-transparent display region. For example, a region of the display substrate below which a camera and a light sensor are disposed is the transparent display region and other region is the non-transparent display region.

The display substrate includes a base substrate and a plurality of pixels located on the base substrate and in the transparent display region. The plurality of pixels are arranged in a spacing on the base substrate. It is to be noted that the pixels mentioned below all refer to pixels of the transparent display region unless otherwise stated.

The pixels each include a plurality of sub-pixels. The sub-pixels each include an organic light-emitting element and a pixel circuit for driving the organic light-emitting element. The organic light-emitting element includes a first electrode, a second electrode and an organic light-emitting material between the first electrode and the second electrode. The first electrodes of the sub-pixels are electrically connected with the pixel circuits. In some embodiments, the first electrode may be anodes and the second electrode may be cathodes. The first electrode is located at a side of the organic light-emitting material close to the substrate, and the second electrode is located at a side of the organic light-emitting material away from the substrate. Each pixel may include three sub-pixels with different luminous colors, for example, may include a red sub-pixel, a green sub-pixel and a blue sub-pixel.

In an embodiment, the display substrate further includes a pixel definition layer provided with pixel openings in one-to-one correspondence with the sub-pixels. The pixel openings are used to define the light-emitting regions of the sub-pixels.

In some embodiments, the organic light-emitting material is located at a side of the first electrodes away from the base substrate. The first electrode of each sub-pixel is in contact with the organic light-emitting material at the pixel openings of the pixel definition layer, and the pixel opening of the pixel definition layer defines a shape of the light-emitting region of the sub-pixel. For example, the first electrodes of the organic light-emitting elements (e.g. anode electrodes) may be disposed below the pixel definition layer, and the pixel openings of the pixel definition layer expose a part of the first electrodes. When the organic light-emitting material is formed in the pixel openings of the above pixel definition layer, the organic light-emitting material is in contact with the first electrodes, and thus, these first electrodes can drive the organic light-emitting material to emit light.

In some embodiments, an orthographic projection of the pixel opening of the pixel definition layer on the base substrate is located within an orthographic projection of the corresponding organic light-emitting material on the base substrate, that is, the organic light-emitting material covers the pixel openings of the pixel definition layer. For example, an area of the organic light-emitting material is greater than an area of the corresponding pixel opening, that is, the organic light-emitting material at least includes a portion that covers a part of a solid structure of the pixel definition layer in addition to a portion within the corresponding pixel opening. Generally, the solid structures of the pixel definition layer located at the boundaries of the pixel openings are all covered with the organic light-emitting material. It is to be noted that the descriptions about a pattern of the organic light-emitting material is based, for example, on the organic light-emitting material of each sub-pixel patterned by using FMM process. In addition to the FMM manufacturing process, an open mask process is used for some organic light-emitting materials to form an integral film layer on the display region, with an orthographic projection of its shape on the base substrate being continuous. Thus, it is natural that the organic light-emitting material includes a portion located within the pixel openings and a portion on the solid structure of the pixel definition layer.

In an embodiment, a number of the first electrodes is greater than a number of the second electrodes. The display substrate is further provided with first power supply signal lines and second power supply signal lines. The pixel circuits are connected with the first power supply signal lines, and the second electrodes are connected with the second power supply signal lines. The first power supply signal lines include first sub-power supply signal lines extending along a first direction and second sub-power supply signal lines extending along a second direction; and/or, the second power supply signal lines include third sub-power supply signal lines extending along the first direction and fourth sub-power supply signal lines extending along the second direction. The first direction intersects with the second direction.

In the display substrate provided by the embodiments of the present application, since the number of the first electrodes is greater than the number of the second electrodes, at least two sub-pixels share one second electrode. If the second electrode of each sub-pixel is disposed independently, each second electrode is to be disposed to have a relatively large area to overlap with the second power supply signal lines. In the embodiments of the present application, at least two sub-pixels share one second electrode, which reduces a total area of the second electrodes of the transparent display region, thus helping increase the light transmission rate of the transparent display region of the display substrate. Disposing one of the first power supply signal lines and the second power supply signal lines as a grid-shaped structure helps to reduce a voltage drop of the first power supply signal lines and the second power supply signal lines and increase the uniformity of the display effect of the display substrate.

In an embodiment, the sub-pixels of the pixel may share one second electrode. For example, when a pixel includes a red sub-pixel, a green sub-pixel and a blue sub-pixel, the red sub-pixel, the green sub-pixel and the blue sub-pixel in the pixel may share one second electrode. No second electrode is disposed in a region between adjacent pixels to ensure the light transmission rate of the display substrate.

In an embodiment, the first power supply signal lines may be high-level power supply signal lines and the second power supply signal lines may be low-level power supply signal lines.

In some embodiments, the first direction is a column direction and the second direction is a row direction. In some embodiments, the pixel circuits for the sub-pixels of each pixel are arranged in a spacing along the second direction.

The transparent display region of the display substrate includes a light-emitting region and a non-light-emitting region. The region outside the light-emitting region is the non-light-emitting region. The pixels are located in the light-emitting region, which means the pixel circuits, the first electrodes, the organic light-emitting material and some second electrodes of the pixels are located in the light-emitting region.

In an embodiment, a region covered by an orthographic projection of the pixel circuit of the sub-pixel on the base substrate is substantially located within one rectangular box. The orthographic projection of the pixel circuit on the base substrate mainly includes the orthographic projection of the structure of the elements such as transistors and capacitors on the base substrate. The display substrate further includes a plurality of signal lines used to drive the pixel circuits. It is to be noted that some signal lines include a part within the rectangular box and a part extending out of the rectangular box.

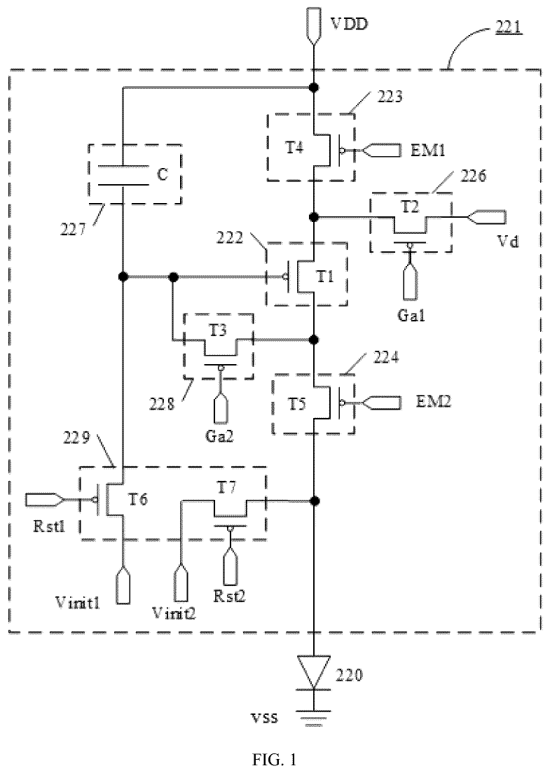

In an embodiment, as shown in FIG. 1, the pixel circuit 221 includes a drive circuit 222. The drive circuit 222 includes a control end, a first end and a second end and is configured to provide a drive current for driving the organic light-emitting element 220 to emit light for the organic light-emitting element 220.

In an embodiment, as shown in FIG. 1, the pixel circuit 221 includes a first light-emitting control circuit 223 and a second light-emitting control circuit 224. For example, the first light-emitting control circuit 223 is connected to the first end of the drive circuit 222 and a first voltage end VDD and configured to connect or disconnect the drive circuit 222 and the first voltage end VDD. The second light-emitting control circuit 224 is electrically connected to the second end of the drive circuit 222 and the first electrode of the organic light-emitting element 220 and configured to connect or disconnect the drive circuit 222 and the organic light-emitting element 220.

In an embodiment, as shown in FIG. 1, the pixel circuit 221 further includes a data write circuit 226, a storage circuit 227, a threshold compensation circuit 228 and a reset circuit 229. The data write circuit 226 is electrically connected to the first end of the drive circuit 222 and configured to write data signals into the storage circuit 227 under the control of the scan signals. The storage circuit 227 is electrically connect to the control end of the drive circuit 222 and the first voltage end VDD, and configured to store data signals. The threshold compensation circuit 228 is electrically connected to the control end and the second end of the drive circuit 222 and configured to perform threshold compensation for the drive circuit 222. The reset circuit 229 is electrically connected to the control end of the drive circuit 222 and the first electrode of the organic light-emitting element 220, and configured to perform resetting for the control end of the drive circuit 222 and the first electrode of the organic light-emitting element 220 under the control of reset control signals.

In an embodiment, as shown in FIG. 1, the drive circuit 222 includes a drive transistor T1, the control end of the drive circuit 222 includes a gate electrode of the drive transistor T1, the first end of the drive circuit 222 includes a first electrode of the drive transistor T1, and the second end of the drive circuit 222 includes a second electrode of the drive transistor T1.

In an embodiment, as shown in FIG. 1, the data write circuit 226 includes a data write transistor T2, the storage circuit 227 includes a capacitor C, the threshold compensation circuit 228 includes a threshold compensation transistor T3, the first light-emitting control circuit 223 includes a first light-emitting control transistor T4, the second light-emitting control circuit 224 includes a second light-emitting control transistor T5, the reset circuit 229 includes a first reset transistor T6 and a second reset transistor T7, and the reset control signals may include a first sub-reset control signal and a second sub-reset control signal.

In an embodiment, as shown in FIG. 1, a first electrode of the data write transistor T2 is electrically connected to the first electrode of the drive transistor T1, a second electrode of the data write transistor T2 is configured to be electrically connected with a data line Vd to receive data signals, and a gate electrode of the data write transistor T2 is configured to be electrically connected with a scan signal line Ga1 to receive scan signals; a first electrode of the capacitor C is electrically connected to the first power supply end VDD, and a second electrode of the capacitor C is electrically connected to the gate electrode of the drive transistor T1; a first electrode of the threshold compensation transistor T3 is electrically connected to the second electrode of the drive transistor T1, a second electrode of the threshold compensation transistor T3 is electrically connected to the gate electrode of the drive transistor T1, and a gate electrode of the threshold compensation transistor T3 is configured to be electrically connected to a scan signal line Ga2 to receive compensation control signals; a first electrode of the first reset transistor T6 is configured to be electrically connected to a reset power supply end Vinit1 to receive the first reset signals, a second electrode of the first reset transistor T6 is electrically connected to the gate electrode of the drive transistor T1, and a gate electrode of the first reset transistor T6 is configured to be electrically connected to a reset control signal line Rst1 to receive the first sub-reset control signals; a first electrode of the second reset transistor T7 is configured to be electrically connected to a reset power supply end Vinit2 to receive the second reset signals, a second electrode of the second reset transistor T7 is electrically connected to the first electrode of the organic light-emitting element 220, and a gate electrode of the second reset transistor T7 is configured to be electrically connected to a reset control signal line Rst2 to receive the second sub-reset control signals; a first electrode of the first light-emitting control transistor T4 is electrically connected to the first power supply end VDD, a second electrode of the first light-emitting control transistor T4 is electrically connected to the first electrode of the drive transistor T1, and a gate electrode of the first light-emitting control transistor T4 is configured to be electrically connected to a light-emitting control signal line EM1 to receive first light-emitting control signals; a first electrode of the second light-emitting control transistor T5 is electrically connected to the second electrode of the drive transistor T1, a second electrode of the second light-emitting control transistor T5 is electrically connected to the first electrode of the organic light-emitting element 220, and a gate electrode of the second light-emitting control transistor T5 is configured to be electrically connected to a light-emitting control signal line EM2 to receive second light-emitting control signals; the second electrode of the organic light-emitting element 220 is electrically connected to a second power supply end vss.

In an embodiment, one of the first power supply end VDD and the second power supply end vss is a high voltage end and the other is a low voltage end. In the embodiment shown in FIG. 1, the first power supply end VDD is a voltage source to supply a constant first voltage which is a positive voltage; the second power supply end vss is a voltage source to supply a constant second voltage which is a negative voltage and the like. In some exemplary embodiments, the second power supply end vss may be grounded.

In an embodiment, as shown in FIG. 1, the scan signal and the compensation control signal may be same, that is, the gate electrode of the data write transistor T2 and the gate electrode of the threshold compensation transistor T3 may be electrically connected to a same signal line, for example, scan signal line Ga1, to receive same signals (e.g. scan signals). At this time, the display substrate may not be provided with the scan signal line Ga2 to reduce the number of the scan signal lines. For another example, the gate electrode of the data write transistor T2 and the gate electrode of the threshold compensation transistor T3 may be connected to different signal lines respectively, that is, the gate electrode of the data write transistor T2 is electrically connected to the scan signal line Ga1, and the gate electrode of the threshold compensation transistor T3 is electrically connected to the scan signal line Ga2, where the signals transmitted by the scan signal line Ga1 and the scan signal line Ga2 are same.

It should be noted that, the scan signal and the compensation control signal may also be different, such that the gate electrode of the data write transistor T2 and the gate electrode of the threshold compensation transistor T3 can be controlled separately, thus increasing the flexibility of controlling the pixel circuit.

In an embodiment, as shown in FIG. 1, the first light-emitting control signal and the second light-emitting control signal may be same, that is, the gate electrode of the first light-emitting control transistor T4 and the gate electrode of the second light-emitting control transistor T5 may be electrically connected to a same signal line, for example, the light-emitting control signal line EM1, to receive same signals (e.g. first light-emitting control signals). At this time, the display substrate may not be provided with the light-emitting control signal line EM2 to reduce the number of the signal lines. In other embodiments, the gate electrode of the first light-emitting control transistor T4 and the gate electrode of the second light-emitting control transistor T5 may be electrically connected to different signal lines, that is, the gate electrode of the first light-emitting control transistor T4 is electrically connected to the light-emitting control signal line EM1 and the gate electrode of the second light-emitting control transistor T5 is electrically connected to the light-emitting control signal line EM2, where the signals transmitted by the light-emitting control signal line EM1 and the light-emitting control signal line EM2 are same.

It should be noted that when the first light-emitting control transistor T4 and the second light-emitting control transistor T5 are different types of transistors, for example, the first light-emitting control transistor T4 is a P type transistor and the second light-emitting control transistor T5 is an N-type transistor, the first light-emitting control signal and the second light-emitting control signal may be different, which is not limited herein.

In an embodiment, the first sub-reset control signal and the second sub-reset control signal may be same, that is, the gate electrode of the first reset transistor T6 and the gate electrode of the second reset transistor T7 may be electrically connected to a same signal line, for example, the reset control signal line Rst1, to receive same signals (e.g. first sub-reset control signals). At this time, the display substrate may not be provided with the reset control signal line Rst2 to reduce the number of signal lines. For another example, the gate electrode of the first reset transistor T6 and the gate electrode of the second reset transistor T7 may be electrically connected to different signal lines, that is, the gate electrode of the first reset transistor T6 is electrically connected to the reset control signal line Rst1 and the gate electrode of the second reset transistor T7 is electrically connected to the reset control signal line Rst2, where the signals transmitted by the reset control signal line Rst1 and the reset control signal line Rst2 are same. It should be noted that the first sub-reset control signal and the second sub-reset control signal may also be different. In another embodiment, the first sub-reset control signal and the second sub-reset control signal are different, a pulse width of the reset control signal line Rst2 is greater than a pulse width of the reset control signal line Rst1, and the pulse width of the reset control signal line Rst2 is less than a pulse width of the light-emitting control signal line EM2 when the second light-emitting control transistor T5 is cut off. In this way, the service life of the organic light-emitting element of the sub-pixel is increased.

In an embodiment, the second sub-reset control signal may be same as the scan signal, that is, the gate electrode of the second reset transistor T7 may be electrically connected to the scan signal line Ga1 to receive scan signals as the second sub-reset control signal.

In an embodiment, the source electrode of the first reset transistor T6 and a source electrode of the second reset transistor T7 are respectively connected to the first reset power supply end Vinit1 and the second reset power supply end Vinit2. The first reset power supply end Vinit1 and the second reset power supply end Vinit2 may be DC reference voltage ends to output constant DC reference voltages. The first reset power supply end Vinit1 and the second reset power supply end Vinit2 may be same, for example, the source electrode of the first reset transistor T6 and a source electrode of the second reset transistor T7 are connected to a same reset power supply end. The first reset power supply end Vinit1 and the second reset power supply end Vinit2 may be high-voltage ends or low-voltage ends as long as they can provide the first reset signals and the second reset signals to perform resetting on the gate electrode of the drive transistor T1 and the first electrode of the organic light-emitting element 220, which is not limited herein.

It should be noted that the drive circuit 222, the data write circuit 226, the storage circuit 227, the threshold compensation circuit 228 and the reset circuit 229 in the pixel circuit shown in FIG. 1 are only illustrative, and the specific structures of the circuits such as the drive circuit 222, the data write circuit 226, the storage circuit 227, the threshold compensation circuit 228 and the reset circuit 229 may be set based on actual application requirements, which is not limited in the embodiments of the present application.

According to the characteristics of the transistors, the transistors may be divided into N-type transistors and P-type transistors. For purpose of clarity, the technical solution of the present application is detailed with the transistor being a P-type transistor (e.g. P-type MOS transistor) in the embodiments of the present application. That is, in the descriptions of the present application, the drive transistor T1, the data write transistor T2, the threshold compensation transistor T3, the first light-emitting control transistor T4, the second light-emitting control transistor T5, the first reset transistor T6 and the second reset transistor T7 are all P-type transistors. Of course, the transistors in the embodiments of the present application are not limited to the P-type transistors. Those skilled in the art may implement the functions of one or more transistors in the embodiments of the present application by using the N-type transistors (e.g. N-type MOS transistors) based on actual requirements.

It should be noted that the transistors used in the embodiments of the present application may be thin film transistors or field effect transistors or other switching devices with same characteristics. The thin film transistor may include an oxide semiconductor thin film transistor, an amorphous-silicon thin film transistor, a polysilicon thin film transistor or the like. The source electrode and the drain electrode of the transistor may be structurally symmetrical, thus the source electrode and the drain electrode are structurally undistinguishable. In an embodiment of the present application, to distinguish transistors, except for the gate electrode as control electrode, one electrode is described as the first electrode and the other electrode is described as the second electrode. Therefore, the first electrode and the second electrode of all or part of the transistors in the embodiments of the present application can be interchangeable based on actual needs.

It should be noted that in the embodiments of the present application, the pixel circuit of the sub-pixel may also be a structure including another number of transistors, for example, 7T2C structure, 6T1C structure, 6T2C structure or 9T2C structure in addition to the 7T1C (seven transistors and one capacitor) structure shown in FIG. 1, which is not limited herein.

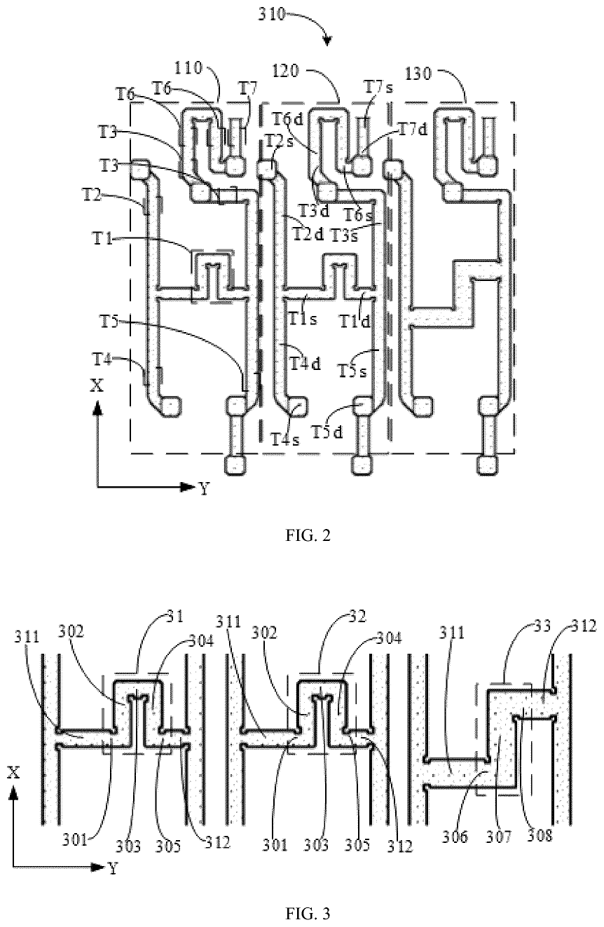

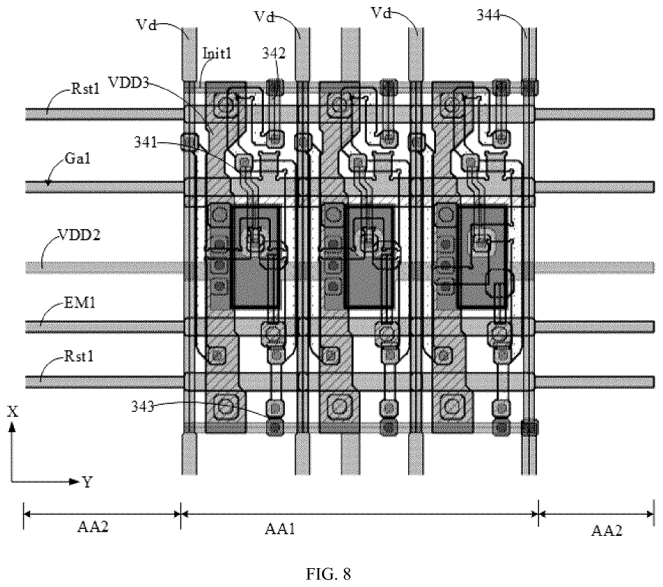

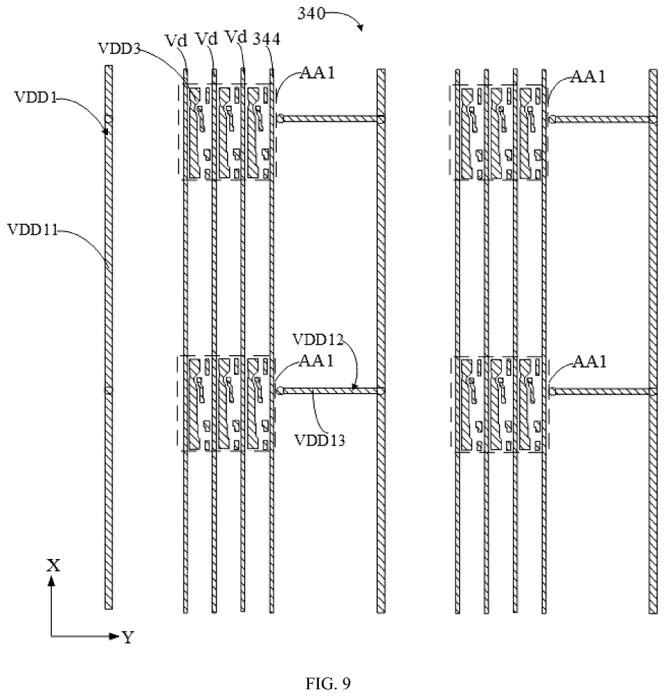

FIGS. 2 to 7 are schematic diagrams of layers of a display substrate according to an embodiment of the present application. FIG. 8 is a schematic diagram of overlaying of some film layers of a display substrate. The positional relationship of circuits and signal lines in a pixel circuit on a backplate are described by referring to FIGS. 2 to 8. As shown in FIGS. 2 to 8, with the pixel circuit 221 of one pixel as an example, the positions of the transistors of the pixel circuit of a sub-pixel 110 are illustrated, and the positions of the components included in the pixel circuits of a sub-pixel 120 and a sub-pixel 130 are substantially same as the positions of the transistors included in the sub-pixel 110. It can be seen from FIGS. 2 to 7 that the pixel circuit is located in a light-emitting region AA1, some signal lines are only in the light-emitting region AA1 and some signal lines is partially in the light-emitting region AA1 and partially in the non-light-emitting region AA2. As shown in FIG. 2, the pixel circuit 221 of the sub-pixel 110 includes the drive transistor T1, the data write transistor T2, the threshold compensation transistor T3, the first light-emitting control transistor T4, the second light-emitting control transistor T5, the first reset transistor T6, the second reset transistor T7 and the capacitor C as shown in FIG. 1.

FIGS. 2 to 8 also show the scan signal line Ga1, the reset control signal line Rst1, the reset power supply signal line Init1, the light-emitting control signal line EM1, the data line Vd, the second sub-power supply signal line VDD12 of the first power supply signal line VDD1 connected to the first power supply end VDD, the second power supply signal line VSS connected to the second power supply end vss and the shielding line 344 in the pixel circuit 221 of each sub-pixel electrically connected to a same pixel. FIGS. 2 to 7 also show the third power supply signal line VDD2, the fourth power supply signal line VDD3, and the fifth power supply signal line VDD4, where the third power supply signal line VDD2, the fourth power supply signal line VDD3, and the fifth power supply signal line VDD4 are electrically connected to the first power supply signal line VDD1 respectively.

The scan signal line Ga1 is configured to provide scan signals for the pixels; the reset control signal line Rst1 and the reset control signal line Rst2 are configured to provide reset control signals for the pixels; the reset power supply signal line Init1 is configured to provide reset power supply signals for the pixels; the light-emitting control signal line EM1 is configured to provide light-emitting control signals for the pixels; the data line Vd is configured to provide light-emitting data signals for the pixels; the first power supply signal line VDD1 and the second power supply signal line VSS are configured to provide power supply signals for the pixels.

For example, FIG. 2 illustrates an active semiconductor layer 310 of the pixel circuits of the display substrate. The active semiconductor layer 310 may be formed by patterning a semiconductor material. The active semiconductor layer 310 may be used to manufacture channels of the drive transistor T1, the data write transistor T2, the threshold compensation transistor T3, the first light-emitting control transistor T4, the second light-emitting control transistor T5, the first reset transistor T6, the second reset transistor T7. The active semiconductor layer 310 includes the channels and the source and drain regions (i.e. the source regions s and the drain regions d shown in the sub-pixel 120) of each transistor of each sub-pixel, and the channels and the source and drain regions of each transistor of a same pixel circuit are integrally disposed.

It is to be noted that the active semiconductor layer may include an integrally-formed low-temperature polysilicon layer, where the source region and the drain region may be subjected to conductorization through doping or the like to achieve electrical connection of the structures. The active semiconductor layer of each transistor of each sub-pixel is an integral pattern formed by a p-silicon, and each transistor of a same pixel circuit includes a source and drain region (i.e. source region s and drain region d) and a channel, and the channels of different transistors are separated by the source and drain region.

In an embodiment, the active semiconductor layers of the pixel circuits of the sub-pixels of different colors arranged in the second direction are not connected but disconnected with each other. The active semiconductor layers of the pixel circuits of the sub-pixels of same color arranged in the first direction may be integrally disposed or disconnected with each other.

As shown in FIG. 3, in at least one pixel, channels 31 and 32 of the drive transistor T1 of at least one sub-pixel include a first section 301, a second section 302, a third section 303, a fourth section 304 and a fifth section 305 connected in sequence. The first section 301, the third section 303, and the fifth section 305 all extend along the second direction Y, and the second section 302 and the fourth section 304 both extend along the first direction X. A channel 33 of the drive transistor T1 of at least one sub-pixel includes a sixth section 306, a seventh section 307 and an eighth section 308 connected in sequence. The sixth section 306 and the eighth section 308 both extend along the second direction Y, and the seventh section 307 extends along the first direction X. In this way, with a given space occupied by the sub-pixel, the width-to-length ratios of the channels of the drive transistors of the sub-pixels of different colors on the display substrate are optimized to improve the brightness of the display substrate. In this embodiment, the width-to-length ratio of the channel 33 is greater than the width-to-length ratios of the channels 31 and 32. In some embodiments, the channel 31 and the channel 32 may be channels of the red sub-pixel and the green sub-pixel, and the channel 33 may be a channel of the blue sub-pixel.

In an embodiment, as shown in FIG. 3, the drive transistor T1 of the sub-pixel includes first source and drain region 311 and second source and drain region 312. The first source and drain region and the second source and drain region of the drive transistor T1 of at least one sub-pixel are different in length. One of the first source and drain region 311 and the second source and drain region 312 is a source region and the other is a drain region. In the drive transistor T1 where the channels 31 and 32 are located, the first source and drain region 311 is connected with the first section 301, and the second source and drain region 312 is connected with the fifth section 305. In the drive transistor T1 where the channel 33 is located, the first source and drain region 311 is connected with the sixth section 306, and the second source and drain region 312 is connected with the eighth section 308. In this way, the signal write of the pixel circuit can be optimized and the light blocking design of the channels can also be optimized.

In an embodiment shown in FIG. 3, in the drive transistors T1 where the channels 31, 32 and 33 are located respectively, the first source and drain region 311 and the second source and drain region 312 are different in length.

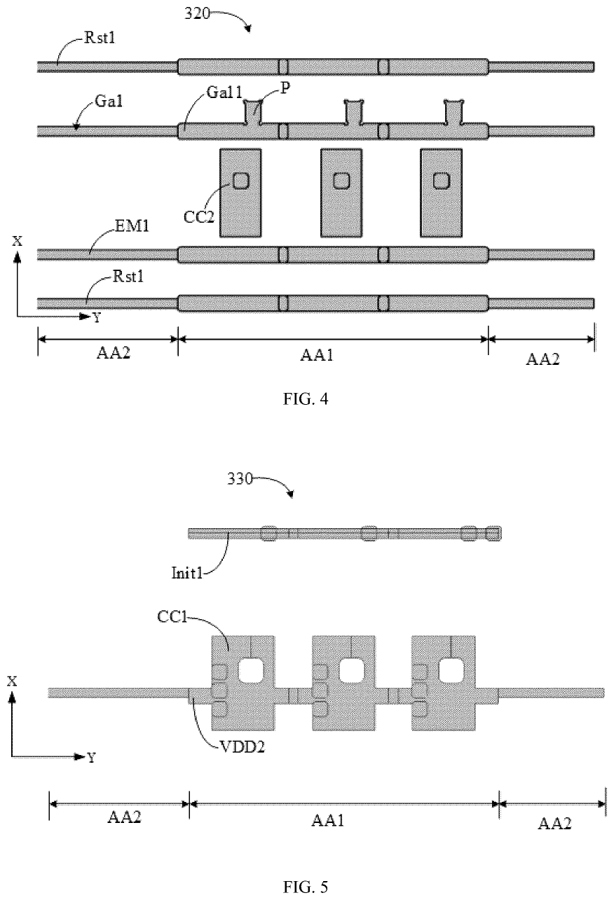

For example, a gate metal layer of the pixel circuit may include a first conductive layer and a second conductive layer. A gate insulation layer is formed on the above active semiconductor layer 310 to protect the above active semiconductor layer 310. The active semiconductor layer 310 is located on the base substrate 100. As shown in FIG. 4, the display substrate includes a first conductive layer 320 which is disposed on the gate insulation layer to be insulated from the active semiconductor layer 310. The first conductive layer 320 may include a second plate CC2 of the capacitor C, the scan signal line Ga1, the reset control signal line Rst1, the light-emitting control signal line EM1, and the gate electrodes of the drive transistor T1, the data write transistor T2, the threshold compensation transistor T3, the first light-emitting control transistor T4, the second light-emitting control transistor T5, the first reset transistor T6 and the second reset transistor T7. The scan signal line Ga1 includes a scan signal line body portion Ga11 and a protruding portion P protruding from a side of the scan signal line body portion Ga11.

For example, as shown in FIG. 4, the gate electrode of the data write transistor T2 may be an overlapping part of the scan signal line Ga1 and the active semiconductor line 310; the gate electrode of the first light-emitting control transistor T4 may be a first part where the light-emitting control signal line EM1 and the active semiconductor layer 310 are overlapped, and the gate electrode of the second light-emitting control transistor T5 may be a second part where the light-emitting control signal line EM1 and the active semiconductor layer 310 are overlapped; the gate electrode of the first reset transistor T6 may be a first part where the reset control signal line Rst1 and the active semiconductor layer 310 are overlapped, and the gate electrode of the second reset transistor T7 may be a second part where the reset control signal line Rst1 and the active semiconductor layer 310 are overlapped; the threshold compensation transistor T3 may be a thin film transistor with double-gate structure. The first gate electrode of the threshold compensation transistor T3 may be a part where the scan signal line Ga1 and the active semiconductor layer 310 are overlapped, and the second gate electrode of the threshold compensation transistor T3 may be a part where the protruding portion P of the scan signal line Ga1 and the active semiconductor layer 310 are overlapped. As shown in FIGS. 1 and 4, the gate electrode of the drive transistor T1 may be the second plate CC2 of the capacitor C.

It is to be noted that the dashed line rectangular boxes in FIG. 2 illustrate the overlapping parts of the first conductive layer 320 and the active semiconductor layer 310.

For example, as shown in FIG. 4, the scan signal line Ga1, the reset control signal line Rst1 and the light-emitting control signal line EM1 are arranged up and down in the first direction X, and the scan signal line Ga1, the reset control signal line Rst1 and the light-emitting control signal line EM1 extend in the second direction Y. The signal lines extending along the second direction means the signal lines generally extend in the second direction, where an area of a part of the signal lines extending along the second direction is far greater than an area of a part extending along the first direction; the signal lines extending along the first direction means the signal lines generally extend along the first direction, where an area of a part of the signal lines extending along the first direction is far greater than an area of a part extending along the second direction.

For example, in the first direction X, the second plate CC2 of the capacitor C (i.e. the gate electrode of the drive transistor T1) is located between the scan signal line Ga1 and the light-emitting control signal line EM1. The protruding portion P of the scan signal line Ga1 is located at a side of the scan signal line Ga1 away from the light-emitting control signal line EM1.

For example, as shown in FIG. 2, in the first direction X, the gate electrode of the data write transistor T2, the gate electrode of the threshold compensation transistor T3, the gate electrode of the first reset transistor T6 and the gate electrode of the second reset transistor T7 are all located at a first side of the gate electrode of the drive transistor T1, and the gate electrode of the first light-emitting control transistor T4 and the gate electrode of the second light-emitting control transistor T5 both are located at a second side of the gate electrode of the drive transistor T1. For example, in the examples shown in FIGS. 2 to 7, the first side and the second side of the gate electrode of the drive transistor T1 of the pixel circuit of a sub-pixel of first color are two opposed sides of the gate electrode of the drive transistor T1 in the first direction X. For example, as shown in FIGS. 2 to 8, in an XY plane, the first side of the gate electrode of the drive transistor T1 of the pixel circuit of the sub-pixel 110 may be an upper side of the gate electrode of the drive transistor T1, and the second side of the gate electrode of the drive transistor T1 of the pixel circuit of the sub-pixel 110 may be a lower side of the gate electrode of the drive transistor T1. For the lower side, for example, a side of the display substrate for bonding a drive chip is a lower side of the display substrate, and the lower side of the gate electrode of the drive transistor T1 is a side, closer to the drive chip, of the gate electrode of the drive transistor T1. The upper side is an opposed side of the lower side, for example, a side, further away from the drive chip, of the gate electrode of the drive transistor T1.

For example, in some embodiments, as shown in FIGS. 2 to 8, in the second direction Y, the gate electrode of the data write transistor T2 and the gate electrode of the first light-emitting control transistor T4 both are located at a third side of the gate electrode of the drive transistor T1, and the first gate electrode of the threshold compensation transistor T3, the gate electrode of the second light-emitting control transistor T5 and the gate electrode of the second reset transistor T7 are all located at a fourth side of the gate electrode of the drive transistor T1. For example, in the examples shown in FIGS. 2 to 8, the third side and the fourth side of the gate electrode of the drive transistor T1 of the pixel circuit of the sub-pixel 110 are two opposed sides of the gate electrode of the drive transistor T1 in the second direction Y. For example, as shown in FIGS. 2 to 7, the third side of the gate electrode of the drive transistor T1 of the pixel circuit of the sub-pixel 110 may be a left side of the gate electrode of the drive transistor T1 of the pixel circuit of the sub-pixel 110, and the fourth side of the gate electrode of the drive transistor T1 of the pixel circuit of the sub-pixel 110 may be a right side of the gate electrode of the drive transistor T1 of the pixel circuit of the sub-pixel 110. For the left and right sides, for example, in a same pixel circuit, the data line is located at the left side of the first power supply signal line VDD1 and the first power supply signal line VDD1 is at the right side of the data line.

For example, a first insulation layer is formed on the above first conductive layer 320 to protect the above first conductive layer 320. FIG. 5 illustrates a second conducive layer 330 of the pixel circuit, which includes the first plate CCI of the capacitor C, the reset power supply signal line Init1 and the third power supply signal line VDD2. The third power supply signal line VDD2 and the first plate CCI of the capacitor C are integrally formed. The first plate CCI and the second plate CC2 of the capacitor C are at least partially overlapped to form the capacitor C.

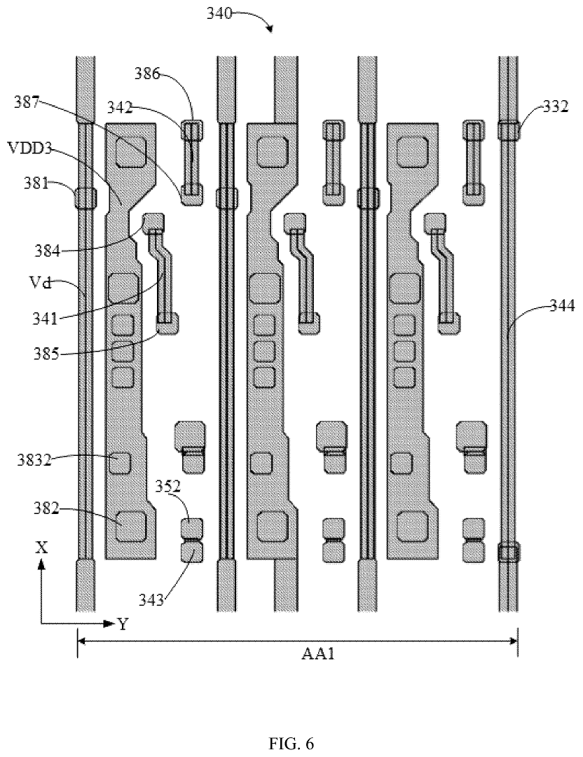

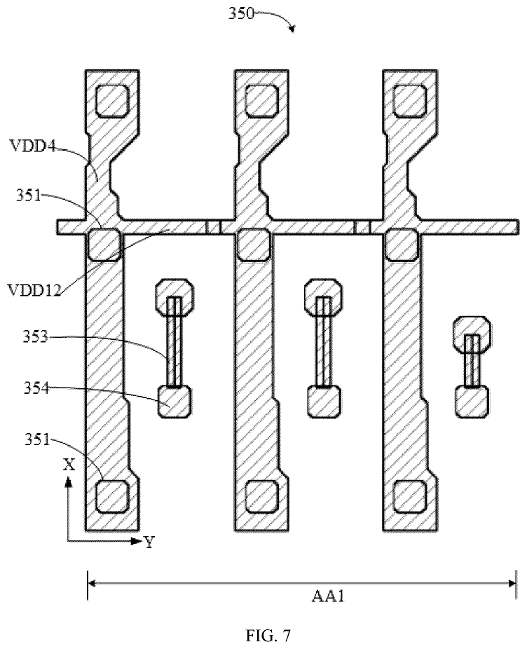

For example, a second insulation layer is formed on the above second conductive layer 330 to protect the above second conductive layer 330. FIG. 6 illustrates a source and drain electrode metal layer 340 of the pixel circuit, which includes the data line Vd, the fourth power supply signal line VDD3 and the shielding line 344. The data line Vd, the fourth power supply signal line VDD3 and the shielding line 344 as mentioned above all extend along the first direction X. The shielding line 344 and the data line Vd are disposed with a same material in a same layer such that the shielding line and the data line can be formed simultaneously in one patterning process, avoiding additional patterning process for manufacturing the shielding line thus simplifying the manufacturing flow of the display substrate and saving the manufacturing cost. For example, the source and drain electrode metal layer 340 further includes a connection structure 341, a connection portion 342, and a first sub-electrode connection structure 343 of the electrode connection portion. One end of the connection structure 341 is connected with the gate electrode of the drive transistor T1 and the other end of the connection structure 341 is connected with the source and drain region of the threshold compensation transistor T3.

FIG. 6 further shows the exemplary positions of a plurality of via holes. The source and drain electrode metal layer 340 is connected with a plurality of film layers between the source and drain electrode metal layer 340 and the base substrate through the plurality of via holes. For example, the source and drain electrode metal layer 340 is connected to the active semiconductor layer 310 shown in FIG. 2 through a via hole 381, a via hole 382, a via hole 384, a via hole 387 and a via hole 352, and connected to the second conductive layer 330 shown in FIG. 5 through a via hole 3832, a via hole 386, a via hole 385 and a via hole 332.

For example, a third insulation layer and a fourth insulation layer are formed on the above source and drain electrode metal layer 340 to protect the above source and drain electrode metal layer 340. The organic light-emitting element of each sub-pixel may be disposed at sides of the third insulation layer and the fourth insulation layer away from the base substrate.

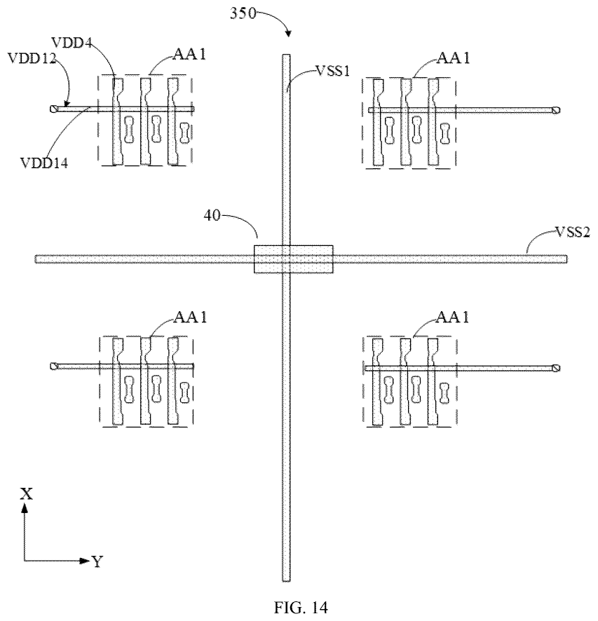

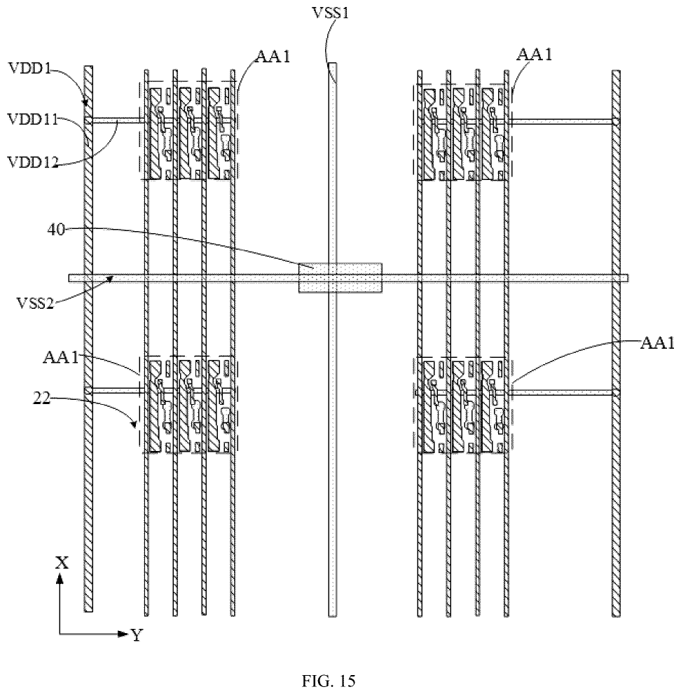

FIG. 7 illustrates a third conductive layer 350 of the pixel circuit, which includes second sub-electrode connection structures 353 of the electrode connection portion, the second sub-power supply signal line VDD12 of the first power supply signal line VDD1 extending along the second direction and the fifth power supply signal lines VDD4 extending along the first direction X, where the second sub-power supply signal line VDD12 intersects with each fifth power supply signal line VDD4. The specific structure of the first power supply signal line VDD1 will be described in the following FIGS. 9 to 16. FIG. 7 also shows the exemplary positions of a plurality of via holes 351 and via holes 354. The third conductive layer 350 is connected to the source and drain electrode metal layer 340 through the plurality of via holes 351 and via holes 354.

FIG. 8 is a schematic diagram illustrating an overlaying relationship of the active semiconductor layer 310, the first conductive layer 320, the second conductive layer 330, the source and drain electrode metal layer 340 and the third conductive layer 350. As shown in FIGS. 2 to 8, the data line Vd is connected to the source region of the data write transistor T2 in the active semiconductor layer 310 through at least one via hole (e.g. the via hole 381) in the gate insulation layer, the first insulation layer and the second insulation layer. The fourth power supply signal line VDD3 is connected to the source region of the corresponding first light-emitting control transistor T4 in the active semiconductor layer 310 through at least one via hole (e.g. the via hole 382) in the gate insulation layer, the first insulation layer and the second insulation layer.

As shown in FIGS. 2 to 8, one end of the connection structure 341 is connected to the drain region of the corresponding threshold compensation transistor T3 in the active semiconductor layer 310 through at least one via hole (e.g. the via hole 384) in the gate insulation layer, the first insulation layer and the second insulation layer, and the other end of the connection structure 341 is connected to the gate electrode (i.e. the second plate CC2 of the capacitor C) the drive transistor T1 in the first conductive layer 320 through at least one via hole (e.g. the via hole 385) in the first insulation layer and the second insulation layer. One end of the connection portion 342 is connected to the reset power supply signal line Init1 through one via hole (e.g. the via hole 386) in the second insulation layer, and the other end of the connection portion 342 is connected to the drain region of the second reset transistor T7 in the active semiconductor layer 310 through at least one via hole (e.g. the via hole 387) in the gate insulation layer, the first insulation layer and the second insulation layer. The first sub-electrode connection structure 343 is connected to the drain region of the second light-emitting control transistor T5 in the active semiconductor layer 310 through at least one via hole (e.g. the via hole 352) in the gate insulation layer, the first insulation layer and the second insulation layer. It is to be noted that the source region and the drain region of the transistors used in the embodiments of the present application may be structurally same, and thus its source region and drain region are structurally undistinguishable. Therefore, the source region and the drain region may be interchangeable.

For example, as shown in FIGS. 2 to 7, the fourth power supply signal line VDD3 is connected to the first plate CCI of the capacitor C in the second conductive layer 330 through at least one via hole (e.g. the via hole 3832) in the second insulation layer between the second conductive layer 330 and the source and drain electrode metal layer 340.

For example, as shown in FIGS. 2 to 8, the shielding line 344 extends along the first direction X, and an orthographic projection of the shielding line 344 on the base substrate is located between orthographic projections of the corresponding data lines of two adjacent pixels on the base substrate. For example, the shielding line can reduce the influence of the signals transmitted on the corresponding data lines of two adjacent pixels on the performance of the threshold compensation transistor T3, thus mitigating the crosstalk problem.

For example, as shown in FIGS. 2 to 8, the shielding line 344 is connected to the reset power supply signal line Init1 through at least one via hole (e.g. the via hole 332) in the second insulation layer. In this case, the shielding line is enabled to have a fixed potential and further the voltage of the initialization signals transmitted on the reset power supply signal line is made more stable, thus helping the working performance of the pixel driving circuit.

For example, as shown in FIGS. 2 to 8, the shielding line 344 is electrically connected to the reset power supply signal line to enable the shielding line to have a fixed potential. The shielding line 344 may be electrically connected to two reset power supply signal lines Init1 extending along the Y direction, and the two reset power supply signal lines Init1 are respectively located at both sides of the shielding line 344 along the X direction. For example, the two reset power supply signal lines correspond to the n-th row of pixel circuits and the (n+1)-th row of pixel circuits respectively.

For example, a same column of shielding line 344 may be one complete shielding line, which may include a plurality of sub-portions between two adjacent reset power supply signal lines, where each sub-portion is located within the region of each pixel circuit of the column. A same column of pixels may share one shielding line 344.

For example, in addition to coupling the shielding line 344 to the reset power supply signal line, the shielding line 344 may also be coupled to the first power supply signal line, such that the shielding line 344 has the same fixed potential as the power supply signals transmitted on the first power supply signal line.

For example, as shown in FIGS. 2 to 7, the fifth power supply signal line VDD4 is connected to the fourth power supply signal line VDD3 through at least one via hole 351 in the third insulation layer and the fourth insulation layer, and the second sub-electrode connection structure 353 is connected to the first sub-electrode connection structure 343 through the via hole 354 in the third insulation layer and the fourth insulation layer.

For example, the third insulation layer may be a passivation layer and the fourth insulation layer may be a planarization layer, and the third insulation layer is located between the fourth insulation layer and the base substrate. The fourth insulation layer may be an organic layer with a thickness greater than a thickness of an inorganic layer such as the passivation layer.

For example, the via hole 351 and the via hole 354 both are nested via holes, that is, the via hole 351 includes a first via hole in the third insulation layer and a second via hole in the fourth insulation layer. The first via hole in the third insulation layer correspond in position to the second via hole in the fourth insulation layer, and an orthographic projection of the second via hole in the fourth insulation layer on the base substrate is located within an orthographic projection of the first via hole in the third insulation layer on the base substrate.

For example, an orthographic projection of the fifth power supply signal line VDD4 on the base substrate is substantially overlapped with an orthographic projection of the fourth power supply signal line VDD3 on the base substrate, or, the orthographic projection of the fourth power supply signal line VDD3 on the base substrate is located within the orthographic projection of the fifth power supply signal line VDD4 on the base substrate. Further, the fifth power supply signal line VDD4 being electrically connected to the fourth power supply signal line VDD3 may reduce a voltage drop of the first power supply signal line VDD1, thereby improving the uniformity of the display device. For example, the fifth power supply signal line VDD4 may be made of the same material as the source and drain electrode metal layer.

For example, as shown in FIG. 6, the first sub-electrode connection structure 343 of each sub-pixel may be a lump structure. The first electrodes of the sub-pixels of different colors formed subsequently may be connected to the corresponding second sub-electrode connection structures 353 through a via hole to achieve connection with the drain region of the second light-emitting control transistor T5.

In the embodiments of the present application, for example, the position of the second sub-electrode connection structure of each sub-pixel may be determined based on an arrangement rule of the organic light-emitting elements and the position of the light-emitting region.

For example, the first sub-electrode connection structure 343 of each sub-pixel is connected to the second electrode T5d of the second light-emitting control transistor T5 in the active semiconductor layer through the via hole 352 in the gate insulation layer, the first insulation layer and the second insulation layer. The first sub-electrode connection structure 343 is overlapped with the third power supply signal line VDD2 and the light-emitting control signal line EM1 respectively. The second sub-electrode connection structure 353 is connected to the first sub-electrode connection structure 343 through the nested via hole 354 in the third insulation layer and the fourth insulation layer, thus achieving connection with the second light-emitting control transistor.

For example, the data line Vd is connected to the source electrode T2s of the data write transistor T2 through the via hole 381 in the gate insulation layer, the first insulation layer and the second insulation layer; one end of the connection structure 341 is connected to the drain electrode T3d of the threshold compensation transistor T3 through the via hole 384 in the gate insulation layer, the first insulation layer and the second insulation layer, and the other end of the connection structure 341 is connected to the gate electrode of the drive transistor T1 (i.e. the second plate CC2 of the capacitor C) through the via hole 385 in the first insulation layer and the second insulation layer; the channel T1c of the drive transistor T1 is located at a side of the gate electrode of the drive transistor T1 facing toward the base substrate and not overlapped with the via hole 385, and the source electrode T1d of the drive transistor T1 is overlapped with both the gate electrode of the drive transistor T1 and the first plate CC1 of the capacitor C.

It is to be noted that the positional arrangement relationship of the drive circuit, the first light-emitting control circuit, the second light-emitting control circuit, the data write circuit, the storage circuit, the threshold compensation circuit, the reset circuit and the like in each pixel circuit is not limited to the examples shown in FIGS. 2 to 8 and therefore, the positions of the drive circuit, the first light-emitting control circuit, the second light-emitting control circuit, the data write circuit, the storage circuit, the threshold compensation circuit and the reset circuit can be disposed based on actual requirements.

For example, the first electrode of the sub-pixel 110 is connected to the second sub-electrode connection structure 353 through a via hole (not shown) in a fifth insulation layer, so as to achieve connection with the drain region of the second light-emitting control transistor T5.

As shown in FIGS. 9 to 16, the first power supply signal lines VDD1 include the first sub-power supply signal lines VDD11 extending along the first direction X and the second sub-power supply signal lines VDD12 extending along the second direction Y. The second power supply signal lines VSS include the third sub-power supply signal lines VSS1 extending along the first direction X and the fourth sub-power supply signal lines VSS2 extending along the second direction Y.

The second sub-power supply signal lines VDD12 include first connection signal lines VDD13 and second connection signal lines VDD14. The first connection signal lines VDD13 and the first sub-power supply signal line VDD11 are located in a same layer, and the first connection signal lines VDD13 are connected to the first sub-power supply signal lines VDD11. The first sub-power supply signal lines VDD11 and the first connection signal lines VDD13 may be located in the source and drain electrode metal layer 340. The second connection signal lines VDD14 and the first connection signal lines VDD13 are located in different layers. The second connection signal lines VDD14 may be located in the third conductive layer 350.

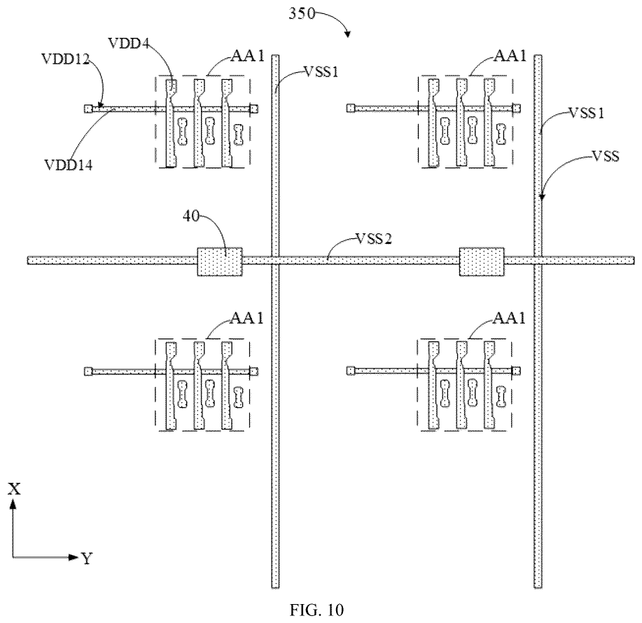

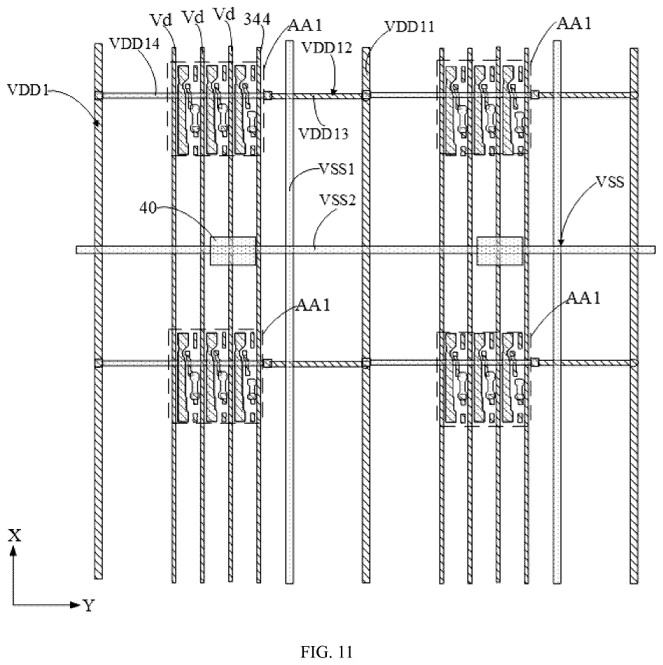

For example, as shown in FIGS. 10 and 11, the second connection signal lines VDD14 intersect with the fifth power supply signal lines VDD4, and the second connection signal lines VDD14 are connected to the first connection signal lines VDD13 through a via hole in the third insulation layer and the fourth insulation layer.

The third sub-power supply signal lines VSS1 and the fourth sub-power supply signal lines VSS2 of the second power supply signal lines VSS are intersected and may be located in a same layer. The third sub-power supply signal lines VSS1 and the fourth sub-power supply signal lines VSS2 may be located in the third conductive layer 350.

In an embodiment, as shown in FIGS. 10 to 12 and 14 to 16, the display substrate further includes overlapping portions 40 connected with the second power supply signal lines VSS. The overlapping portions 40 and the second power supply signal lines VSS may be disposed in a same layer.

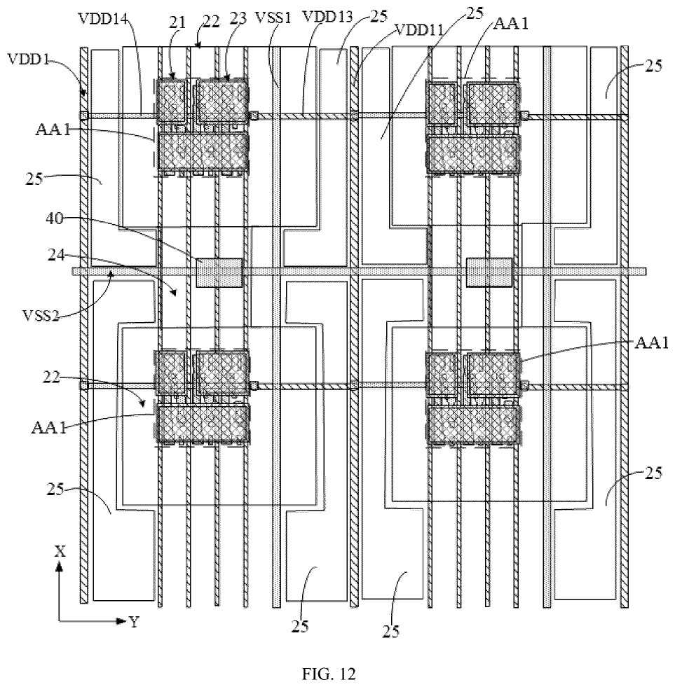

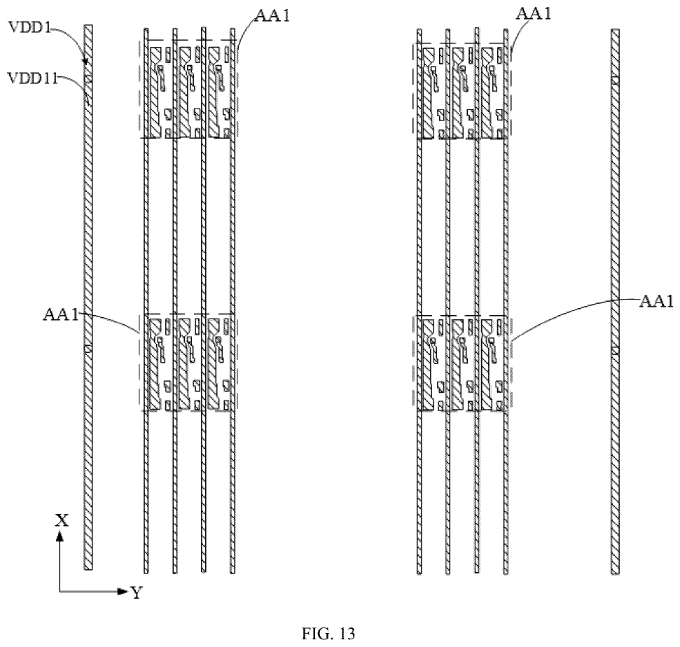

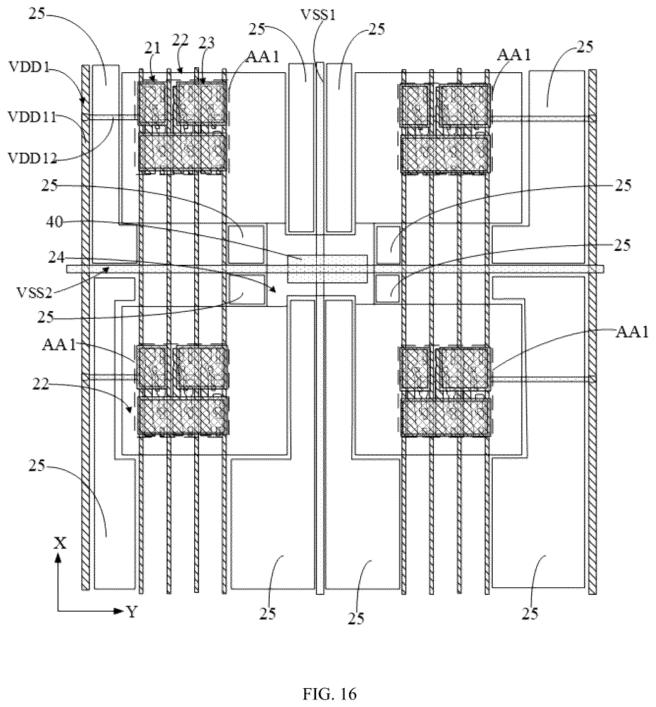

As shown in FIGS. 12 and 16, the sub-pixel includes a first electrode 21 and a second electrode 22, and the sub-pixels in a same pixel share one second electrode 22. The display substrate further includes a pixel definition layer provided with a plurality of pixel openings 23. The first electrodes 21 and the pixel openings 23 are located in the light-emitting regions AA1. Each sub-pixel corresponds to one pixel opening, and an orthographic projection of the pixel opening 23 of the sub-pixel on the base substrate is located within an orthographic projection of the first electrode 21 on the base substrate.

In an embodiment, as shown in FIG. 12, the second electrodes 22 of at least two adjacent pixels are in contact with a same overlapping portion 40. The contact between the second electrodes and the overlapping portion means that the second electrodes are in contact with the overlapping portion through a contact hole of the insulation layer between the second electrodes and the overlapping portion. In this way, the second electrodes 22 of two adjacent pixels are in contact with a same overlapping portion so as to achieve electrical connection with the second power supply signal line VSS. Compared with the solution in which the second electrodes of each pixel are in contact with different overlapping portions, the numbers of the overlapping portions and the contact holes are reduced and the light transmission rate of the display substrate is increased. Moreover, in the solution in which the second electrodes of each pixel are connected to the second power supply signal lines through a same overlapping portion, the second electrodes of each pixel need to be large enough to overlap with the overlapping portion 40 in a film layer lamination direction so as to contact with the overlapping portion. In the present embodiment, by enabling the second electrodes of at least two adjacent pixels to be in contact with a same overlapping portion 40, a total area of the second electrodes in the display substrate can be reduced, helping to increase the light transmission rate of the display substrate. Further, in this embodiment, the number of the sub-power supply signal lines of the second power supply signal lines VSS can be reduced, thus helping increase the light transmission rate of the display substrate.

Furthermore, the second electrodes 22 of at least two adjacent pixels are electrically connected to the third sub-power supply signal line VSS1 through a same overlapping portion 40, or electrically connected to the fourth sub-power supply signal line VSS2 through a same overlapping portion 40. In the embodiment shown in FIG. 12, the second electrodes 22 of two adjacent pixels are electrically connected to a same fourth sub-power supply signal line VSS2 through a same overlapping portion 40. In other embodiments, the second electrodes 22 of two adjacent pixels may be electrically connected to a same third sub-power supply signal line VSS1 through a same overlapping portion 40.

In a plurality of sub-pixels of the display substrate, multiple pixels arranged in a spacing along the second direction Y are referred to as one row of pixels and multiple pixels arranged in a spacing along the first direction X are referred to as one column of pixels.

In an embodiment, the second electrodes of two adjacent rows of sub-pixels may be connected to a same fourth sub-power supply signal line VSS2 through an overlapping portion respectively. Specifically, in two adjacent row of pixels, the second electrodes of two adjacent pixels along the first direction X are in contact with a same overlapping portion 40. In this way, compared with the solution in which the second electrodes of different rows of pixels are connected to different fourth sub-power supply signal lines VSS2, the number of the fourth sub-power supply signal lines VSS2 can be reduced by half.

Furthermore, a plurality of overlapping portions 40 arranged in a spacing along the second direction Y are disposed between two adjacent rows of sub-pixels, and the plurality of overlapping portions 40 arranged along the second direction Y are electrically connected through the fourth sub-power supply signal line VSS2.

In another embodiment, the second electrodes of two adjacent columns of pixels may be connected to a same third sub-power supply signal line VSS1 through an overlapping portion respectively. Specifically, in two adjacent columns of sub-pixels, the second electrodes of two adjacent sub-pixels along the second direction Y are in contact with a same overlapping portion 40. In this way, compared with the solution in which the second electrodes of different columns of pixels are connected to different third sub-power supply signal lines VSS1, the number of the third sub-power supply signal lines VSS1 can be reduced by half.

In this embodiment, a plurality of overlapping portions 40 arranged in a spacing along the first direction X are disposed between two adjacent columns of pixels, and the plurality of overlapping portions 40 arranged along the first direction X are electrically connected through the third sub-power supply signal line VSS1.

In an embodiment, as shown in FIG. 16, the second electrodes of at least four adjacent pixels are in contact with a same overlapping portion 40, and the four adjacent pixels are arranged into two rows and two columns. In this way, a total area of the second electrodes of the display substrate is reduced, the number of the overlapping portions is reduced, and the number of the sub-power supply signal lines of the second power supply signal lines VSS is also reduced, thereby helping to increase the light transmission rate of the display substrate.

Furthermore, an orthographic projection of the overlapping portion 40 on the base substrate is located between orthographic projections of the second electrodes 22 of the four adjacent pixels on the base substrate.

Furthermore, as shown in FIG. 16, the second electrodes 22 of at least four adjacent pixels are connected to the third sub-power supply signal line VSS1 and the fourth sub-power supply signal line VSS2 through a same overlapping portion 40. The four adjacent pixels are arranged into two rows and two columns. One fourth sub-power supply signal line VSS2 is disposed between the two rows of pixels, one third sub-power supply signal line VSS1 is disposed between the two columns of pixels, and the overlapping portion 40 is located between the four pixels. Therefore, the overlapping portion 40 is connected to both the third sub-power supply signal line VSS1 and the fourth sub-power supply signal line VSS2.

Furthermore, at least one overlapping portion 40 is electrically connected to other overlapping portions arranged in the first direction X through the third sub-power supply signal line VSS1, and connected to other overlapping portions arranged in the second direction Y through the fourth sub-power supply signal line VSS2. This helps to reduce the number of the sub-power supply signal lines of the second power supply signal lines VSS, so as to increase the light transmission rate of the display substrate.

In an embodiment, the display substrate includes a plurality of overlapping portions 40, each of which is in contact with the second electrodes of four adjacent pixels respectively. The plurality of overlapping portions 40 are arranged into multiple rows and multiple columns. A plurality of overlapping portions arranged in the first direction X are connected through the third sub-power supply signal line VSS1, and a plurality of overlapping portions arranged in the second direction Y are connected through the fourth sub-power supply signal line VSS2.

In an embodiment, as shown in FIGS. 12 and 16, the display substrate further includes electrode connection structures 24 connected to the second electrodes. The second electrodes in contact with a same overlapping portion 40 are connected to a same electrode connection structure 24. The second electrodes 22 are in contact with the overlapping portion 40 through the electrode connection structure 24. The electrode connection structure 24 corresponding to a plurality of second electrodes 22 in contact with a same overlapping portion 40 is located between the plurality of second electrodes 22 to facilitate the connection between the electrode connection structure 24 and the second electrodes 22. The electrode connection structure 24 and the second electrodes 22 may be disposed in a same layer.

In an embodiment, the first power supply signal lines VDD1 include a plurality of sub-power supply signal lines VDD11 and VDD12, each of which extends along the first direction or the second direction. The pixel circuits of at least two adjacent pixels are connected with a same sub-power supply signal line of the first power supply signal lines. Thus, the number of the sub-power supply signal lines of the first power supply signal lines VDD1 can be reduced and the light transmission rate of the display substrate can be improved. In the embodiment shown in FIG. 12, the pixel circuits of two adjacent sub-pixels along the second direction Y are connected to a same first sub-power supply signal line VDD11.

In an embodiment, as shown in FIGS. 9 to 16, at least one first sub-power supply signal line VDD11 of the first power supply signal lines VDD1 is electrically connected to the pixel circuit through the second sub-power supply signal line VDD12; at least part of the second sub-power supply signal lines VDD12 and the first sub-power supply signal lines VDD11 are disposed in different layers. With this disposal, short circuiting between the drive signal lines for driving pixels in the source and drain electrode metal layer 340 and the second sub-power supply signal lines VDD12 can be avoided. In the embodiments shown in FIGS. 9 to 16, the second sub-power supply signal lines VDD12 include first connection signal lines VDD13 and second connection signal lines VDD14, and the second connection signal lines VDD14 and the first sub-power supply signal lines VDD11 are disposed in different layers.

Furthermore, the display substrate further includes drive signal lines disposed in the same layer as the first sub-power supply signal lines, where the drive signal lines are configured to provide drive signals for the pixel circuits. An orthographic projection of the part of the second sub-power supply signal lines VDD12 disposed in a different layer from the first sub-power supply signal lines VDD11 on the base substrate is overlapped with an orthographic projection of the drive signal lines on the base substrate. In this way, it can be ensured that the first sub-power supply signal line VDD11 are electrically connected to the pixel circuits through the second sub-power supply signal lines VDD12, and short circuiting between the second sub-power supply signal lines VDD12 and the drive signal lines can be avoided. In the embodiments shown in FIGS. 9 to 16, the drive signal lines include data lines Vd. The second connection signal lines VDD14 of the second sub-power supply signal lines VDD12 and the first sub-power supply signal lines VDD11 are disposed in different layers. An orthographic projection of the second connection signal lines VDD14 on the base substrate is overlapped with an orthographic projection of the data lines Vd on the base substrate.

In an embodiment, as shown in FIGS. 12 to 16, the pixel definition layer is provided with openings 25 located in the non-light-emitting region AA2. By disposing the openings 25 located in the non-light-emitting region AA2 in the pixel definition layer, the light transmission rate of the non-light-emitting region AA2 can be increased. A plurality of openings 25 can be disposed in the pixel definition layer.

Furthermore, as shown in FIGS. 12 to 16, at least part of orthographic projection of the openings 25 on the base substrate is located outside the orthographic projection of the second electrodes 22 on the base substrate, the orthographic projection of the second power supply signal lines VSS on the base substrate and the orthographic projection of the first power supply signal lines VDD1 on the base substrate.

In the embodiments shown in FIGS. 12 and 16, the orthographic projection of the openings 25 on the base substrate all is located outside the orthographic projections of the second electrodes 22 on the base substrate. In this way, small height difference of the film layers below the second electrodes 22 can be avoided and thus climbing breakage of the second electrodes 22 can be avoided.

In the embodiments shown in FIGS. 12 and 16, the orthographic projection of the openings 25 on the base substrate is located outside the orthographic projection of the first power supply signal lines VDD1 on the base substrate. Specifically, the orthographic projection of the openings 25 on the base substrate is located outside the orthographic projection of the first sub-power supply signal lines VDD11 of the first power supply signal lines VDD1 on the base substrate, and the orthographic projection of the openings 25 on the base substrate is partially overlapped with the orthographic projection of the second sub-power supply signal lines VDD12 of the first power supply signal lines VDD1 on the base substrate.

In the embodiments shown in FIGS. 12 and 16, the orthographic projection of the openings 25 on the base substrate all is located outside the orthographic projection of the second power supply signal lines VSS on the base substrate.

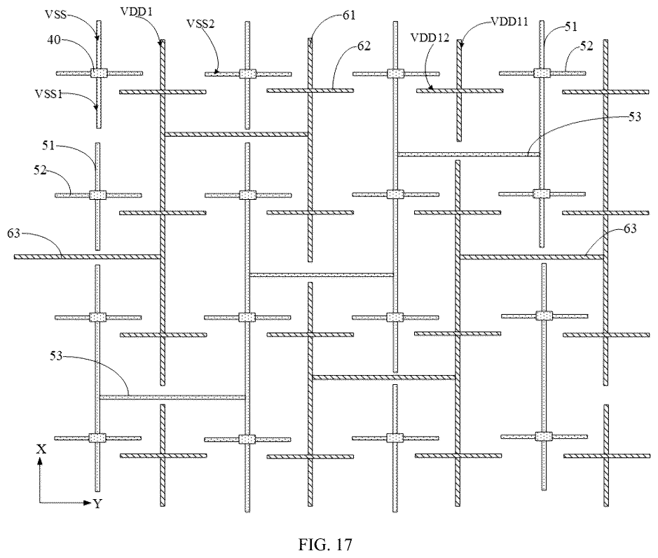

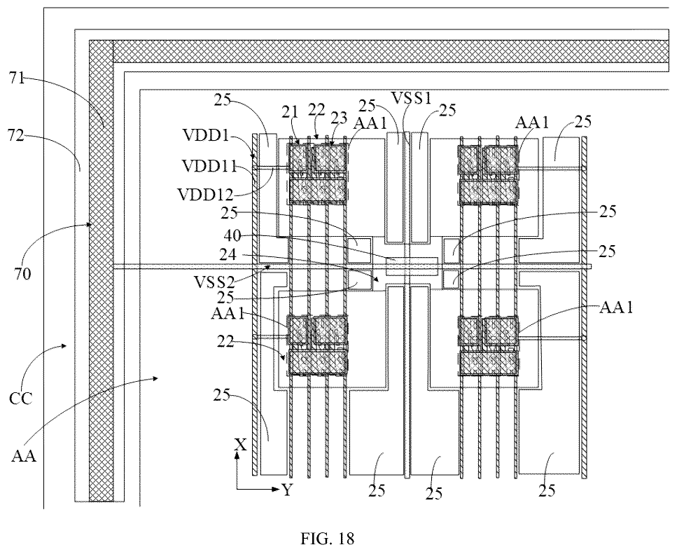

In an embodiment, as shown in FIG. 17, the orthographic projection of the first power supply signal lines VDD1 on the base substrate is not overlapped with the orthographic projection of the second power supply signal lines VSS on the base substrate. In this way, it is avoided that the first power supply signal lines VDD1 and the second power supply signal lines VSS are overlapped along the film layer lamination direction of the display substrate, which reduces the light transmission rate of the overlapping regions, thus affecting the light transmission rate of the display substrate. Furthermore, it can be avoided that more heat is generated at the overlapping regions of the first power supply signal lines VDD1 and the second power supply signal lines VSS during a working process of the display panel, resulting in easy occurrence of burns in the overlapping regions. In this way, the service life of the display substrate can be extended.

In an embodiment, as shown in FIG. 17, the first power supply signal lines VDD1 include first sub-power supply signal lines VDD11 extending along the first direction X, second sub-power supply signal lines VDD12 extending along the second direction Y and a plurality of first connection segments 63 extending along the second direction Y. The second power supply signal lines VSS include third sub-power supply signal lines VSS1 extending along the first direction X, fourth sub-power supply signal lines VSS2 extending along the second direction Y and a plurality of second connection segments 53 extending along the second direction Y. Each first sub-power supply signal line VDD11 includes a plurality of first sub-signal segments 61 arranged in a spacing along the first direction X, and each second sub-power supply signal line VDD12 includes a plurality of second sub-signal segments 62 arranged in a spacing along the second direction Y. Each first sub-signal segment 61 is connected to at least one second sub-signal segment 62 and the orthographic projections of the connected first sub-signal segment 61 and second sub-signal segment 62 on the base substrate are intersected. Each third sub-power supply signal line VSS1 includes a plurality of third sub-signal segments 51 arranged in a spacing along the first direction X, and each fourth sub-power supply signal line VSS2 includes a plurality of fourth sub-signal segments 52 arranged in a spacing along the second direction Y. Each third sub-signal segment 51 is connected to at least one fourth sub-signal segment 52, and the orthographic projections of the connected third sub-signal segment 51 and fourth sub-signal segment 52 on the base substrate are intersected.

The adjacent first sub-signal segments 61 along the second direction Y are connected through the first connection segment 63, and an orthographic projection of at least one first connection segment 63 on the base substrate is located between orthographic projections of two adjacent third sub-signal segments 51 on the base substrate. Adjacent third sub-signal segments 51 along the second direction Y are connected through the second connection segment 53. An orthographic projection of at least one second connection segment 53 on the base substrate is located between orthographic projections of two adjacent first sub-signal segments 61 on the base substrate.

In the above disposal, each first sub-signal segment 61 and each second sub-signal segment 62 of the first power supply signal lines VDD1 are electrically connected, and each third sub-signal segment 51 and each fourth sub-signal segment 52 of the second power supply signal lines VSS are electrically connected. Further, the overlapping region of the orthographic projections of the first power supply signal lines VDD1 and the second power supply signal lines on the base substrate can be reduced, so as to improve the light transmission rate and the service life of the display substrate.

Furthermore, the orthographic projection of each first connection segment 63 on the base substrate is located between the orthographic projections of two adjacent third sub-signal segments 51 on the base substrate, and the orthographic projection of each second connection segment 53 on the base substrate is located between the orthographic projections of two adjacent first sub-signal segments 61 on the base substrate. In this case, the orthographic projections of the first power supply signal lines VDD1 and the second power supply signal lines on the base substrate are not overlapped.

In an embodiment, the first connection segments 63 and the first sub-power supply signal lines VDD11 of the first power supply signal lines VDD1 may be disposed in a same layer, and the second connection segments 53 and the second power supply signal lines VSS may be disposed in a same layer. In this way, the manufacturing process complexity of the display substrate can be reduced.

In an embodiment, the display substrate is further provided with a plurality of drive signal lines configured to provide drive signals for the pixel circuits. A width of a part of at least one drive signal line located in the light-emitting region is greater than a width of a part located in the non-light-emitting region. By making the width of the drive signal lines in the non-light-emitting region smaller, the light transmission rate of the non-light-emitting region can be increased so as to improve the light transmission rate of the display substrate. By making the width of the drive signal lines in the light-emitting region larger, it is avoided that a larger resistance of the drive signal lines in the light-emitting region quickly heats up the light-emitting region.

As shown in FIGS. 4 and 5, the drive signal lines include a reset control signal line Rst1, a scan signal line Ga1, a light-emitting control signal line EM1, and a third power supply signal line VDD2. The widths of parts of the reset control signal line Rst1, the reset control signal line Rst2, the scan signal line Ga1, the light-emitting control signal line EM1, and the third power supply signal line VDD2 located in the light-emitting region AA1 are all greater than the widths of parts in the non-light-emitting region AA2.

In an embodiment, a width of a part of at least one scan signal line Ga1 in the light-emitting region AA1 is greater than a width of a part in the non-light-emitting region AA2; the part of the scan signal line Ga1 in the light-emitting region AA1 has a width of 3.5 μm to 5.5 μm, and the part of the scan signal line Ga1 in the non-light-emitting region AA2 has a width of 2 μm to 3.5 μm. By setting the width of the part of the scan signal line Ga1 in the non-light-emitting region AA2 to 2 μm to 3.5 μm, it is avoided that the part of the scan signal line Ga1 in the non-light-emitting region AA2 has a larger resistance due to smaller width and the part of the scan signal line Ga1 in the non-light-emitting region AA2 affects the light transmission rate of the non-light-emitting region due to larger width. In some embodiments, the part of the scan signal line Ga1 in the light-emitting region AA1 has a width of 3.5 μm, 3.8 μm, 4.0 μm, 4.5 μm, 5.0 μm, 5.5 μm or the like, and the part of the scan signal line Ga1 in the non-light-emitting region AA2 has a width of 2 μm, 2.3 μm, 2.5 μm, 3.0 μm, 3.2 μm, 3.5 μm or the like.

In an embodiment, as shown in FIG. 18, the display substrate further includes a frame region CC at at least one side of the display region AA. The display substrate further includes an auxiliary trace 70 located in the frame region CC. The auxiliary trace 70 is electrically connected with the second electrodes 22. The auxiliary trace 70 may be electrically connected to the second electrodes 22 through the second power supply signal lines VSS. The auxiliary trace can reduce the resistance of the second electrodes 22 so as to improve the IR drop problem of the second electrodes 22.

The auxiliary trace 70 includes a first conductive film layer 71 and a second conductive film layer located at a side of the first conductive film layer away from the base substrate. An edge, close to the display region AA, of an orthographic projection of the first conductive film layer 71 on the base substrate is located within an edge, close to the display region AA, of an orthographic projection of the second conductive film layer 72 on the base substrate. In this way, the overlapping effect of the second conductive film layer 72 and the first conductive film layer 71 can be guaranteed.

Furthermore, an edge, away from the display region AA, of the orthographic projection of the first conductive film layer on the base substrate is located within an edge, away from the display region AA, of the orthographic projection of the second conductive film layer 72 on the base substrate, so as to more effectively guarantee the overlapping effect of the first conductive film layer 71 and the second conductive film layer 72.

In some embodiments, the first conductive film layer 71 and the first electrodes 21 are disposed in a same layer, and the second conductive film layer 72 and the second electrodes 22 are disposed in a same layer. The auxiliary trace 70 may further include a third conductive film layer between the first conductive film layer and the base substrate, which can be located in the source and drain electrode metal layer.

In an embodiment, the display substrate further includes an encapsulation layer above the pixels. The encapsulation layer may be a thin film encapsulation layer including organic layers and inorganic layers arranged alternately, with the top being an inorganic layer.

Embodiments of the present application further provide a display panel, including the display substrate of any one of the above embodiments.

The display panel may further include a glass cover at a side of the display substrate away from the substrate.

Embodiments of the present application further provide a display apparatus, including the above display panel. The display apparatus may further include a housing in which the display panel is embedded.

The display apparatus in the embodiments may be any product or component having a display function, such as electronic paper, smart phone, tablet computer, television, laptop computer, digital photo frame, or vehicle-mounted display device.

It should be noted that in the accompanying drawings, for illustration clarity, the sizes of the layers and regions may be exaggerated. Furthermore, it may be understood that when an element or layer is referred to as being “on” another element or layer, such element or layer may be directly on the another element or layer or there is an intermediate layer therebetween. Further, it is understood that when an element or layer is referred to as being “under” another element or layer, such element or layer may be directly under the another element or layer, or one or more intermediate elements or layers are present therebetween. In addition, it may also be understood that when a layer or element is referred to as being between two layers or elements, such layer or element may be a sole layer between the two layers or elements, or one or more intermediate layers or elements are present. Like reference signs in the descriptions indicate like elements.

Other implementations of the present application will be apparent to those skilled in the art from consideration of the specification and practice of the present application herein. The present application is intended to cover any variations, uses, modification or adaptations of the present application that follow the general principles thereof and include common knowledge or conventional technical means in the related art that are not disclosed in the present application. The specification and examples are considered as exemplary only, with a true scope and spirit of the present application being indicated by the following claims.

It is to be understood that the present application is not limited to the precise structure described above and shown in the accompanying drawings, and that various modifications and changes may be made without departing from the scope thereof. The scope of the present application is limited only by the appended claims.

1. A display substrate, wherein the display substrate comprises a display region, wherein the display region comprises a transparent display region;
wherein the display substrate comprises a base substrate and a plurality of pixels located on the base substrate and in the transparent display region;
wherein the pixels each comprise a plurality of sub-pixels and the sub-pixels each comprise an organic light-emitting element and a pixel circuit configured to driving the organic light-emitting element;
wherein the organic light-emitting element comprises a first electrode, a second electrode and an organic light-emitting material between the first electrode and the second electrode;
wherein the first electrodes of the sub-pixels are electrically connected with the pixel circuits, respectively;
wherein in each of the pixels, at least two of the sub-pixels share a same second electrode so that a number of the first electrodes is greater than a number of the second electrodes;
wherein the display substrate further comprises first power supply signal lines and second power supply signal lines, the pixel circuits are connected with the first power supply signal lines, and the second electrodes are connected with the second power supply signal lines;
wherein the first power supply signal lines comprise first sub-power supply signal lines extending along a first direction and second sub-power supply signal lines extending along a second direction; and/or, the second power supply signal lines comprise third sub-power supply signal lines extending along the first direction and fourth sub-power supply signal lines extending along the second direction, or both the first power supply signal lines comprise first sub-power supply signal lines extending along the first direction and second sub-power supply signal lines extending along the second direction and the second power supply signal lines comprise third sub-power supply signal lines extending along the first direction and fourth sub-power supply signal lines extending along the second direction;
wherein the first direction intersects with the second direction.

2. The display substrate of claim 1, wherein the display substrate further comprises overlapping portions in electrical connection with the second power supply signal lines, and the second electrodes of at least two adjacent pixels are in contact with a same overlapping portion.

3. The display substrate of claim 2, wherein the second power supply signal lines comprise the third sub-power supply signal lines extending along the first direction and the fourth sub-power supply signal lines extending along the second direction, the second electrodes of the at least two adjacent pixels are electrically connected with a third sub-power supply signal line through a same overlapping portion, or electrically connected with a fourth sub-power supply signal line through a same overlapping portion.

4. The display substrate of claim 3, wherein a multitude of the overlapping portions arranged in the first direction are electrically connected through a third sub-power supply signal line, and/or, a multitude of the overlapping portions arranged in the second direction are electrically connected through a fourth sub-power supply signal line.

5. The display substrate of the claim 1, wherein the display substrate further comprises overlapping portions in electrical connection with the second power supply signal lines, the second electrodes of at least four adjacent pixels are in contact with a same overlapping portion, and the four adjacent pixels are arranged into two rows and two columns.

6. The display substrate of claim 5, wherein the second power supply signal lines comprise the third sub-power supply signal lines extending along the first direction and the fourth sub-power supply signal lines extending along the second direction, the second electrodes of the at least four adjacent pixels are electrically connected to a third sub-power supply signal line and a fourth sub-power supply signal line through a same overlapping portion.

7. The display substrate of claim 6, wherein the display substrate comprises a plurality of overlapping portions, and at least one overlapping portion is electrically connected with other overlapping portions arranged in the first direction through a third sub-power supply signal line, and electrically connected with other overlapping portions arranged in the second direction through a fourth sub-power supply signal line.

8. The display substrate of claim 2, wherein the display substrate further comprises electrode connection structures connected with the second electrodes, each of the second electrodes in contact with a same overlapping portion is connected to a same electrode connection structure, and the second electrodes are in contact with the overlapping portion through the electrode connection structure.

9. The display substrate of claim 1, wherein the first power supply signal lines comprise the first sub-power supply signal lines extending along the first direction and the second sub-power supply signal lines extending along the second direction, the pixel circuits of at least two adjacent pixels are connected to a same first sub-power supply signal line or a same second sub-power supply signal line of the first power supply signal lines.

10. The display substrate of claim 1, wherein the first power supply signal lines comprise the first sub-power supply signal lines extending along the first direction and the second sub-power supply signal lines extending along the second direction, at least one first sub-power supply signal line is electrically connected to the pixel circuits through the second sub-power supply signal lines;
wherein at least part of the second sub-power supply signal lines and the first sub-power supply signal lines are disposed in different layers.

11. The display substrate of claim 10, wherein the display substrate further comprises drive signal lines disposed in the same layer as the first sub-power supply signal lines, wherein the drive signal lines are configured to provide drive signals for the pixel circuits;
wherein an orthographic projection of the part of the second sub-power supply signal lines disposed in a different layer from the first sub-power supply signal lines onto the base substrate is overlapped with an orthographic projection of the drive signal lines onto the base substrate.

12. The display substrate of claim 1, wherein an orthographic projection of the first power supply signal lines onto the base substrate is not overlapped with an orthographic projection of the second power supply signal lines onto the base substrate.

13. The display substrate of claim 12, wherein the first power supply signal lines comprise the first sub-power supply signal lines extending along the first direction and the second sub-power supply signal lines extending along the second direction and the second power supply signal lines comprise the third sub-power supply signal lines extending along the first direction and the fourth sub-power supply signal lines extending along the second direction,
wherein the first power supply signal lines further comprise a plurality of first connection segments extending along the second direction;
wherein the second power supply signal lines further comprise a plurality of second connection segments extending along the second direction;
wherein each of the first sub-power supply signal lines comprises a plurality of first sub-signal segments arranged in a spacing along the first direction, each of the second sub-power supply signal lines comprises a plurality of second sub-signal segments arranged in a spacing along the second direction, and each of the first sub-signal segments is connected with at least one second sub-signal segment;
wherein each of the third sub-power supply signal lines comprises a plurality of third sub-signal segments arranged in a spacing along the first direction, each of the fourth sub-power supply signal lines comprises a plurality of fourth sub-signal segments arranged in a spacing along the second direction, and each of the third sub-signal segments is connected with at least one fourth sub-signal segment;
wherein adjacent first sub-signal segments along the second direction are connected through a first connection segment, and adjacent third sub-signal segments along the second direction are connected through a second connection segment;
wherein an orthographic projection of at least one first connection segment on the base substrate is located between orthographic projections of two adjacent third sub-signal segments on the base substrate;
wherein an orthographic projection of at least one second connection segment on the base substrate is located between orthographic projections of two adjacent first sub-signal segments on the base substrate.

14. The display substrate of claim 1, wherein the transparent display region comprises light-emitting regions and non-light-emitting regions;
wherein the pixels are disposed in the light-emitting regions;
wherein the display substrate is further provided with a plurality of drive signal lines;
wherein a width of a part of at least one drive signal line located in the light-emitting regions is greater than a width of a part of the at least one drive signal line located in the non-light-emitting regions.

15. The display substrate of claim 14, wherein the drive signal lines comprise scan signal lines which are configured to provide scan signals for the pixels;
wherein a width of a part of at least one scan signal line located in the light-emitting regions is greater than a width of a part of the at least one scan signal line located in the non-light-emitting regions;
wherein the part of the scan signal line located in the light-emitting regions has a width of 3.5 μm to 5.5 μm, and the part of the scan signal line located in the non-light-emitting regions has a width of 2 μm to 3.5 μm.

16. The display substrate of claim 1, wherein the pixel circuits comprise drive transistors, and the display substrate further comprises an active semiconductor layer comprising a channel of drive transistor of each sub-pixel;
wherein in at least one pixel, the channel of the drive transistor of at least one sub-pixel comprises a first section, a second section, a third section, a fourth section and a fifth section connected in sequence, the first section, the third section and the fifth section all extend along the second direction, and the second section and the fourth section both extend along the first direction;
wherein the channel of the drive transistor of at least one sub-pixel comprises a sixth section, a seventh section, and an eighth section connected in sequence, the sixth section and the eighth section both extend along the second direction, and the seventh section extends along the first direction.

17. (canceled)

18. The display substrate of claim 1, wherein the transparent display region comprises light-emitting regions and non-light-emitting regions, and the pixels are disposed in the light-emitting regions;
wherein the display substrate further comprises a pixel definition layer provided with openings located in the non-light-emitting regions;
wherein at least a part of an orthographic projection of the openings on the base substrate is located outside an orthographic projection of the second electrodes on the base substrate, an orthographic projection of the second power supply signal lines on the base substrate and an orthographic projection of the first power supply signal lines on the base substrate.

19. The display substrate of claim 1, wherein the display substrate further comprises a frame region located at at least one side of the display region, the display substrate further comprises an auxiliary trace located in the frame region, and the auxiliary trace is electrically connected with the second electrodes;
wherein the auxiliary trace comprises a first conductive film layer and a second conductive film layer located at a side of the first conductive film layer away from the base substrate, and an edge, close to the display region, of an orthographic projection of the first conductive film layer on the base substrate is located within an edge, close to the display region, of an orthographic projection of the second conductive film layer on the base substrate.

20. A display panel, comprising the display substrate of claim 1, and a glass cover disposed on a side of the display substrate away from the base substrate.

21. A display apparatus, comprising the display panel of claim 20 and a housing.
